(19) United States
(12) Patent Application Publication
(10) Pub. No.: US 2024/0365510 A1
(43) Pub. Date: Oct. 31, 2024

(54) Heat Pipes Featuring Coefficient of Thermal Expansion Matching and Heat Dissipation Using Same

(71) Applicant: Kuprion Inc., Waterbury, CT (US)

(72) Inventor: Alfred A. Zinn, Palo Alto, CA (US)

(21) Appl. No.: 18/566,137

(22) PCT Filed: Jun. 3, 2022
(86) PCT No.: PCT/US2022/032126

§ 371 Date: Dec. 1, 2023

Related U.S. Application Data
(60) Provisional application No. 63/197,080, filed on Jun. 4, 2021.

(51) Int. Cl. H05K 7/20; H05K 1/02

(52) U.S. Cl. CPC H05K 7/20336; H05K 1/0203; H05K 2201/068

(57) ABSTRACT

Heat pipes may be tailored for coefficient of thermal expansion (CTE) matching with heat-producing components, such as electronic components, in thermal contact therewith. Copper nanoparticles may be consolidated under mild conditions with a CTE modifier to form a copper composite defining a sealed outer shell of a heat pipe, which may contact a heat-producing component for promoting effective heat transfer and robust bonding between the two. A working fluid for promoting heat transfer may be present within an internal space defined within the sealed outer shell. The working fluid may transfer heat from a first location to a second location within the heat pipe. The heat may enter the heat pipe from a heat source contacting the first location, and the heat may exit the heat pipe at the second location through discharge to a suitable heat sink.

### BACKGROUND

Ineffective thermal communication between a heat source and a heat sink can hamper dissipation of excess heat from a system. Heat-generating electronic components, such as high-power LEDs and high-power circuitry, for example, are continually decreasing in size and becoming ever more powerful, thereby generating loads of excess heat that are increasingly being concentrated in smaller and smaller spaces. Growing production of excess heat and concentration thereof can make effective heat removal important yet especially problematic. Failure to remove excess heat from an electronic system can result in significant consequences such as, for example, overheating, reduced conduction, higher power requirements than normal, and/or the need for clock-down operation to avoid board burnout and device failure due to the presence of hot spots.

Ineffective heat conduction can be especially prevalent in circuit boards of various types, particularly printed circuit boards (PCBs). PCBs and similar circuit boards are thermal insulators by the very nature of their construction. Specifically, PCBs may employ thermally insulating substrates (e.g., glass fiber epoxy composites like FR4, which has a thermal conductivity value of approximately 0.25 W/m·K), upon which appropriate electronic circuitry and various board components are disposed. The low thermal conductivity values of PCB substrates can make removal of excess heat from electronic systems rather difficult, since such PCB substrates are incapable by themselves of transferring significant heat to a heat sink. Very little excess heat is capable of being removed via the leads or embedded metal traces due to their typically small size. In addition, conventional lead solder is not especially thermally conductive (e.g., about 1/10^{th} or less than that of more thermally conductive metals, such as copper). Package substrates containing heat-generating devices like GaN- and SiC-based systems, monolithic microwave integrated circuits (MMICs), phased arrays, and the like, such as those found in 5G base stations and power converters, for example, may experience similar heat transfer issues.

Thermal vias are one approach for removing excess heat generated by an electronic component associated with a printed circuit board. However, direct liquid casting of high-melting metals into vias is not compatible with the board materials (substrates) that are presently in use (metal processing temperatures >1000° C. in comparison to much lower polymer melting points for materials typically used as PCB substrates). As such, vias are often packed with rosin or a similar filler and then galvanically capped at the ends or left open, with just a thick metal plating (e.g., copper) formed on the via walls (i.e., the via barrel) to promote electrical communication through the PCB substrate. Galvanic capping is a rather slow process and may afford sub-optimal thermal communication due to the relatively small metal area contacting a heat source at the face of the PCB substrate. Further, galvanic via-filling approaches may leave gaps in a metal plug extending through the PCB, thereby further impacting the thermal conductivity. An alternative approach for filling vias using metal nanoparticles is described in U.S. Pat. No. 10,616,994, incorporated herein by reference, which may promote more complete filling of via holes and afford higher thermal conductivity. Large-diameter vias may be compatible with such processes to provide more effective removal of excess heat. For removing significant quantities of excess heat, however, even thermal vias may be insufficient.

Thermal coins are another approach for heat dissipation that may be used when greater thermal conduction is needed than can be provided by thermal vias. Thermal coins are metal bodies, typically 3-4 mm in diameter, that are pressed into the plane of a PCB or similar substrate and extending therethrough. Although increased thermal conduction relative to thermal vias may result, size misfits of the thermal coins are common, and the thickness of the thermal coins and/or the PCB substrates may vary, which may cause assembly issues when stacking multiple PCB layers together.

Heat pipes are an alternative heat transfer medium that may facilitate transfer of exceptionally large quantities of excess heat. Whereas highly thermally conductive metals, such as copper, may have thermal conductivity values only in the hundreds of W/m·K range, heat pipes may offer much higher effective thermal conductivity values, into the thousands of W/m·K range or even higher, such as about 10,000 W/m·K to about 100,000 W/m·K range. Heat pipes have traditionally been utilized in applications where passive dissipation of heat in rugged operating environments is desirable. Examples include satellites and spacecraft applications. Heat pipes may be advantageous in these and other zero-gravity applications, since heat pipes may operate independently of gravity and orientation. Miniaturized heat pipes have recently been used to dissipate excess heat from printed circuit boards and similar systems containing small heat-producing electronic components in which footprint (size) is critical.

Heat pipes function through direct heat transfer to a working fluid housed within an internal space of a sealed vessel, which may be under atmospheric pressure or preferably a sub-atmospheric pressure (partial vacuum). Heat conduction may be further supplemented by a liquid-vapor phase transition and subsequent condensation of the working fluid. In brief, an outer surface of the heat pipe is in thermal contact with a heat source. Heat from the heat source is conveyed into the sealed vessel and to the working fluid housed therein. Upon being heated, the working fluid and vapors thereof then migrate through the heat pipe to a cooler location (cool end) where the excess heat is dissipated from the heat pipe to a heat sink or similar thermal reservoir. Migration of the working fluid promotes direct transfer of heat to the cooler location. Upon releasing heat, the working fluid and condensed vapors thereof then migrate through the heat pipe to a hotter location (hot end) of the heat pipe for conducting additional heat transfer. Moreover, the entering heat may vaporize the working fluid, which undergoes subsequent condensation at the cooler location to release the stored latent heat. Vaporization and subsequent condensation of the working fluid may significantly increase the amount of heat conducted therewith. After releasing excess heat, preferably after undergoing vaporization and condensation, the working fluid returns to a hotter portion of the heat pipe through capillary action, or another suitable transport means.

A difficulty with utilizing heat pipes to promote heat transfer is that there may be ineffective thermal communication between a heat-producing component and the outer shell of a heat pipe due to coefficient of thermal expansion (CTE) mismatch. Copper, for instance, is a highly thermally conductive metal often utilized for forming the outer shell of heat pipes, but this metal differs considerably in CTE from the ceramic materials commonly used in heat-producing components of printed circuit boards or similar components generating excess heat. The CTE mismatch may lead to disengagement of a heat-producing component from a heat pipe as heating occurs, thereby negating the ability of the heat pipe to dissipate excess heat from the heat-producing component. Moreover, materials used for bonding a heat pipe to a heat-producing component may further contribute to the CTE mismatch issues.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, as will occur to one having ordinary skill in the art and the benefit of this disclosure.

FIGS. 1 and 2 show diagrams of presumed structures of metal nanoparticles having a surfactant coating thereon.

FIG. 3A is a cross-sectional diagram of an illustrative heat pipe comprising a wicking structure adjacent to a hollow core. FIG. 3B is a photo showing a cutaway end view of an illustrative heat pipe comprising a metal mesh or foam wicking structure. FIG. 3C is a diagram showing a cutaway end view of an illustrative heat pipe comprising grooves.

FIG. 4 is a cross-sectional diagram of an illustrative heat pipe comprising a wicking structure adjacent to a hollow core in which a plurality of conductive fibers extend from one end of the heat pipe.

FIG. 5A is a cross-sectional top view of an illustrative oscillating heat pipe. FIG. 5B is a photo showing a perspective view of an illustrative copper block having flow channels defined therein. FIG. 5C is a cross-sectional side view of an illustrative oscillating heat pipe.

FIG. 6 is a diagram showing a heat pipe bonded to a top surface of a heat-producing component.

FIG. 7 is a diagram showing a heat pipe bonded to a bottom surface of a heat-producing component.

FIG. 8 is a diagram showing heat pipes bonded to a top surface and a bottom surface of a heat-producing component.

FIG. 9 is a diagram showing multiple heat pipes bonded to a side surface of a heat-producing component.

FIGS. 10A-10C are diagrams showing side-views of a heat pipe disposed in various locations upon an electrically insulating substrate having high thermal conductivity.

### DETAILED DESCRIPTION

The present disclosure is generally directed to thermal management and, more specifically, to heat pipes having an outer shell having improved coefficient of thermal expansion (CTE) matching to heat-producing components, such as those employed in printed circuit boards (PCBs) and related electronic systems containing various ceramics, including copper cladder boards (CCBs) and boards employing emerging ceramics like AlN and SiN. The heat-producing component may employ an electrically and thermally insulating substrate like FR4 or other polymeric substrates, although substrates that are electrically insulating but thermally conductive, such as AlN, may be employed in some instances. Effective heat dissipation may prove problematic in either case. Through application of the disclosure herein, heat pipes may be fabricated in a manner such that the CTE of the outer shell of the heat pipe may be tailored to match the CTE of a given heat-producing component. The heat pipes may be readily incorporated within PCBs to promote effective and robust heat transfer from a heat-producing component therein to an external heat sink.

As discussed above, removal of excess heat from heat-producing components within circuit boards and related electronic assemblies can be problematic due to the prevalence of thermally insulating materials therein. Heat pipes may be effective for dissipating large amounts of excess heat, but CTE mismatch between metallic components of heat pipes and ceramic materials of electronic components may be significant in many instances. If excessive CTE mismatch is present, a heat pipe may disengage from a heat-producing component, thereby negating the ability of the heat pipe to dissipate excess heat. CTE mismatch may be problematic even in instances where electrically insulating but highly thermally conductive substrates are present, such as AlN and SiN, since it may still be difficult to remove excess heat from a heat-producing electronic component thereon through robust connection of a heat pipe.

The present disclosure provides heat pipes that may afford more effective CTE matching between the heat pipe and a heat-producing component to which the heat pipe may be connected. Alternately, the heat pipes disclosed herein may be effectively CTE matched to a thermally conductive substrate upon which a heat-producing component is disposed. More particularly, the present disclosure provides metal composites comprising a CTE modifier, such as a copper composite, in which a loading of the CTE modifier in the metal composite may be readily modified to promote more effective CTE matching with a given ceramic material in a heat-producing component, such as SiC, GaN, AlN, and the like. The metal composites may form at least a portion of a sealed outer shell of a heat pipe in the disclosure herein. The metal composites may be formed readily from compositions comprising metal nanoparticles, such as copper nanoparticles, which may allow the metal composites and heat pipes to be formed at low temperatures, well below the melting point of molten metals. Additional details regarding metal nanoparticles, such as copper nanoparticles, and various properties that may facilitate low-temperature processing thereof are described hereinbelow.

As described in greater detail hereinbelow, metal nanoparticles may form a bulk metal matrix upon being consolidated with one another. Various addends may be included in the bulk metal matrix to form metal composites. CTE modifiers may alter the CTE of the bulk metal matrix. For example, CTE modifiers may decrease the CTE of a bulk metal matrix formed from copper nanoparticles down to about 11 ppm, or even as low as about 3 ppm in some cases at room temperature, as compared to a value of about 17 ppm typically found for bulk copper. These features may greatly enhance PCB system design and assembly and provide overall product cost reductions while significantly enhancing performance. Exemplary description of how various CTE modifiers may alter the CTE of a copper composite is provided hereinbelow.

In addition to facilitating improved CTE matching between the outer shell of a heat pipe and a ceramic material of an electronic component, metal nanoparticle compositions may also promote direct adhesion (bonding) between an electronic component and a heat pipe by way of a bonding layer. For example, a metal nanoparticle composition may be applied upon an electronic component and contacted with the outer shell of a heat pipe, wherein subsequent consolidation of the metal nanoparticles in the bonding layer may facilitate direct metallurgical bonding to the outer surface of the heat pipe. The direct metallurgical bonding considerably lessens the likelihood of the heat-producing electronic component and the heat pipe becoming disengaged from one another as a result of thermomechanical stress. Because the outer shell of the heat pipe and the bonding layer may be formed from similar materials, there is again less likelihood of CTE mismatch and disengagement resulting from thermomechanical stress as the heat pipe contacts the electronic component. At large electronic component sizes and high operating temperatures (e.g., up to about 350° C.), even small CTE differences may result in high thermomechanical stress values, potentially leading to delamination and eventual device failure. The present disclosure may alleviate this difficulty.

A further advantage afforded by having a bonding layer and/or an outer shell of a heat pipe being formed from consolidated metal nanoparticles is porosity in the resulting metal matrix following metal nanoparticle consolidation. Porosity in the metal matrix may convey flexibility to the bonding layer and/or the outer shell, which may promote enhanced tolerance to thermomechanical stress resulting from any CTE mismatch that still remains present.

Moreover, a still further advantage afforded by the present disclosure is that the metal composites containing a CTE modifier may be applicable to heat pipes of various designs. In particular, the metal composites, such as a copper composite, may be utilized to form both conventional heat pipes having a wicking structure extending within the internals of the heat pipe between a first end (hot end) and a second end (cold end) of the heat pipe, and oscillating heat pipes in which a working fluid moves within a loop comprising a flow channel defined upon an inner surface of the heat pipe. Depending on operational considerations, the loop may be open or closed. The structure housing the flow channel may also be formed from metal nanoparticles as a starting material in the disclosure herein.

The heat pipes of the present disclosure may be utilized in conjunction with printed circuit boards and similar architectures in which a heat-producing component renders heat dissipation problematic. Heat-producing components may be positioned in various locations within a PCB. For example, a location in need of heat dissipation may be present within a heat-producing component located upon a front face of the printed circuit board and directed away from a non-conductive substrate of a PCB, on one or more sides of the heat-producing component, or on an underside of the heat-producing component. In the first two cases, a heat pipe may directly contact the location in need of heat dissipation (e.g., on the front face of the PCB or the front face of a given PCB layer, while in the latter case the heat pipe may contact the underside of the location in need of heat dissipation by further extending through the electrically insulating substrate). In the case of side contact with a heat-producing component, one or more heat pipes may extend laterally across a given PCB layer. Collectively, these configurations for connecting a heat pipe to a heat-producing component may be utilized to facilitate stacking of multiple PCB layers upon one another. Any combination of configurations for connecting a heat pipe to an electronic component may be utilized within a multi-layer PCB to promote heat dissipation therefrom. Moreover, in some stacked configurations, an oscillating heat pipe may be located between adjacent PCB layers, and a wicking heat pipe may be located upon an outermost (top or bottom) of the stacked PCB layers. The heat pipe(s) may be in thermal communication with a structure (or location) for rejecting the excess heat, such as a liquid reservoir, radiator, or like structure functioning as a heat sink.

Similarly, in the case of heat-producing components housed upon electrically insulating but highly thermally conductive substrates, such as AlN or SiN, the heat pipes of the present disclosure may be located upon either face of the substrate, or may be located internally within the substrate. Again, efficient heat transfer and a robust connection of the heat pipe to a location in need of heat removal may be realized. In some cases, the AlN or SiN may be deposited as a thin film (e.g., about 300 microns to about 500 microns in thickness) upon the surface of an electrically insulating substrate to convey thermal conductivity thereto. The relatively thin layer may limit thermal resistance in transferring heat to the heat pipe. Additional details concerning how the heat-producing components may be positioned and how heat pipes may be connected thereto are provided herein. Alternately, when an electrically insulating but thermally conductive substrate is used, the heat pipe may be present upon the substrate rather than contacting the heat-producing component directly, thereby receiving excess heat from the heat-producing component by way of the thermally conductive substrate.

In still other examples, a heat-producing component that is not associated with a substrate may be directly contacted with a heat pipe of the present disclosure, in which case an intermediate layer formed, at least in part, from consolidated metal nanoparticles may be present in between the heat pipe and the heat-producing component. The intermediate layer may provide electrical isolation between the heat pipe and the heat-producing component. For example, a thin AlN film may be bonded to the heat-producing component by way of a first bonding layer formed from metal nanoparticles and to the heat pipe by way of a second bonding layer formed from metal nanoparticles, in which the AlN film provides electrical isolation between the heat pipe and the heat-producing component. CTE matching may be achieved any of these cases.

Metal nanoparticles are uniquely qualified for forming at least a portion of a heat pipe according to the disclosure herein, as well as for forming a bonding layer between the heat pipe and a heat-producing component. Both of these functions may be facilitated as a consequence of the moderate processing conditions needed for consolidating the metal nanoparticles to form bulk metal (e.g., bulk copper) in a metal composite (e.g., a copper composite comprising a CTE modifier). As described in further detail below, metal nanoparticles may be consolidated (fused) together into the corresponding bulk metal under a range of mild processing conditions that are significantly below the melting point of the metal itself. Due to copper's high thermal conductivity and relatively low cost, copper nanoparticles can be a particularly desirable type of metal nanoparticle for use in the various embodiments of the present disclosure. Metal nanoparticles may effectively form a well-dispersed composite when combined with a CTE modifier and consolidated into bulk metal. Suitable CTE modifiers may include, for example, carbon fibers, diamond particles, boron nitride particles, aluminum nitride particles, carbon nanotubes, graphene, W and/or Mo particles, and any combination thereof. W and/or Mo particles may also convey oxidation resistance to copper as an added benefit. In addition to promoting CTE matching within a heat pipe, the CTE modifier and micron-sized metal particles may limit shrinkage during consolidation of metal nanoparticles, which may otherwise exceed 20% in other metal nanoparticle systems. The limited shrinkage may further mitigate thermomechanical stress experienced during operational hot-cold cycling.

In addition to the foregoing advantages, metal nanoparticles may facilitate production of heat pipes having further enhanced structures for dissipating heat therefrom. For example, heat pipes having a wicking structure within an outer shell formed from metal nanoparticles may further comprise a plurality of thermally conductive fibers (e.g., metal fibers, ceramic fibers, carbon fibers, and the like) extending from an end portion of the heat pipe (the cool end). The thermally conductive fibers may facilitate ready dissipation of excess heat to a heat sink, such as ambient atmosphere, a marine environment (e.g., sea, lake or river water), or a radiator for space applications, by providing a high surface area for thermal dissipation. The thermally conductive fibers may be bonded to the heat pipe using a metal nanoparticle composition effective for promoting CTE matching, as described hereinafter. Bonding of the thermally conductive fibers may be accomplished during manufacturing of the heat pipe without a separate bonding step, such as by incorporating the thermally conductive fibers with a suitable metal nanoparticle paste composition prior to metal nanoparticle consolidation taking place to form at least a portion of the heat pipe. In addition, the thermally conductive fibers may optionally extend into an interior space (cavity) of the heat pipe for promoting enhanced thermal communication with a working fluid therein, if desired.

As used herein, the term “metal nanoparticle” refers to metal particles that are about 200 nm or less in size, without particular reference to the shape of the metal particles.

As used herein, the term “micron-scale metal particles” refers to metal particles that are about 200 nm or greater in size in at least one dimension.

The terms “consolidate,” “consolidation” and other variants thereof are used interchangeably herein with the terms “fuse,” “fusion” and other variants thereof.

As used herein, the terms “partially fused,” “partial fusion,” and other derivatives and grammatical equivalents thereof refer to the partial coalescence of metal nanoparticles with one another. Whereas totally fused metal nanoparticles retain only minimal structural morphology of the original unfused metal nanoparticles (i.e., they resemble a dense bulk metal, but have grain boundaries in the 100-500 nm range), partially fused metal nanoparticles retain at least some of the structural morphology of the original unfused metal nanoparticles, such as a higher level of porosity, a smaller average grain size, and a higher number of grain boundaries. The properties of partially fused metal nanoparticles can be intermediate between those of the corresponding bulk metal and the original unfused metal nanoparticles. In some embodiments, fully dense (non-porous) bulk metal can be obtained following metal nanoparticle consolidation to afford a metal composite. In other embodiments, metal composites may have less than about 10% porosity, or less than about 20% porosity, or less than about 30% porosity in an amount above full densification (i.e., >0% porosity). Thus, in particular embodiments, the metal composite may have a porosity ranging from about 2% to about 30%, or about 2% to about 5%, or about 5% to about 10%, or about 10% to about 15%, or about 15% to about 20%, or about 20% to about 25%, or about 25% to about 30%. As indicated above, the porosity may enhance tolerance to thermomechanical stress.

Before discussing more particular aspects of the present disclosure in further detail, additional brief description of metal nanoparticles and their processing conditions, particularly copper nanoparticles, will first be provided. Metal nanoparticles exhibit a number of properties that can differ significantly from those of the corresponding bulk metal. One property of metal nanoparticles that can be of particular importance for processing according to the disclosure herein is nanoparticle fusion (consolidation) that occurs at the metal nanoparticles' fusion temperature. As used herein, the term “fusion temperature” refers to the temperature at which a metal nanoparticle liquefies, thereby giving the appearance of melting. As used herein, the terms “fusion” and “consolidation” synonymously refer to the coalescence or partial coalescence of metal nanoparticles with one another to form a larger mass, such as bulk metal defining the outer shell of a heat pipe or a bonding layer contacting a heat pipe. The fusion temperature may be as much as 80% below the melting point of the corresponding bulk metal. Accordingly, there is at least partial connectivity between the metal nanoparticles following heating above the fusion temperature and subsequently cooling. Following consolidation of the metal nanoparticles, the resulting nanoporosity may accommodate thermal stresses occurring during heating and cooling cycles while still maintaining hermetic sealing of the heat pipe.

Upon decreasing in size, particularly below about 20 nm in equivalent spherical diameter, the temperature at which metal nanoparticles liquefy drops dramatically from that of the corresponding bulk metal. For example, copper nanoparticles having a size of about 20 nm or less can have fusion temperatures of about 235° C. or below, or about 220° C. or below, or about 200° C. or below, in comparison to bulk copper's melting point of 1083° C. Thus, the consolidation of metal nanoparticles taking place at the fusion temperature can allow structures containing bulk metal to be fabricated at significantly lower processing temperatures than when working directly with the bulk metal itself as a starting material. Processing conditions for consolidating metal nanoparticles are typically within normal PCB manufacturing parameters of around 375° F., or even up to about 450° F., and 275-400 psi; however, pressure is not necessarily required for metal nanoparticle fusion to take place. More dense bulk metal may be obtained by applying pressure when promoting metal nanoparticle consolidation. In the case of copper nanoparticles, for example, the fusion temperature is below the temperatures at which commonly used PCB substrates undergo melting or distortion. Thus, metal nanoparticles, such as copper nanoparticles, provide a facile material for forming bulk metal within a heat pipe or a bonding layer to be connected to a heat-producing component within a PCB.

A number of scalable processes for producing bulk quantities of metal nanoparticles in a targeted size range have been developed. Most typically, such processes for producing metal nanoparticles take place by reducing a metal precursor in the presence of one or more surfactants. The metal nanoparticles can then be isolated and purified from the reaction mixture by common isolation techniques and processed into a formulation suitable for dispensation.

Any suitable technique can be employed for forming the metal nanoparticles used in the disclosure herein. Particularly facile metal nanoparticle fabrication techniques are described in U.S. Pat. Nos. 7,736,414, 8,105,414, 8,192,866, 8,486,305, 8,834,747, 9,005,483, 9,095,898, and 9,700,940, each of which is incorporated herein by reference in its entirety. As described therein, metal nanoparticles can be fabricated in a narrow size range by reduction of a metal salt in a solvent in the presence of a suitable surfactant system, which can include one or more different surfactants. Targeted size distributions of metal nanoparticles, including bimodal size distributions, may be obtained by combining metal nanoparticles of different sizes together. Further description of suitable surfactant systems follows below. Without being bound by any theory or mechanism, it is believed that the surfactant system can mediate the nucleation and growth of the metal nanoparticles, limit surface oxidation of the metal nanoparticles, and/or inhibit metal nanoparticles from extensively aggregating with one another prior to being at least partially fused together. Suitable organic solvents for solubilizing metal salts and forming metal nanoparticles can include, for example, formamide, N,N-dimethylformamide, dimethyl sulfoxide, dimethylpropylene urea, hexamethylphosphoramide, tetrahydrofuran, glyme, diglyme, triglyme, tetraglyme, proglyme, or polyglyme. Reducing agents suitable for reducing metal salts and promoting the formation of metal nanoparticles can include, for example, an alkali metal in the presence of a suitable catalyst (e.g., lithium naphthalide, sodium naphthalide, or potassium naphthalide) or borohydride reducing agents (e.g., sodium borohydride, lithium borohydride, potassium borohydride, or tetraalkylammonium borohydrides).

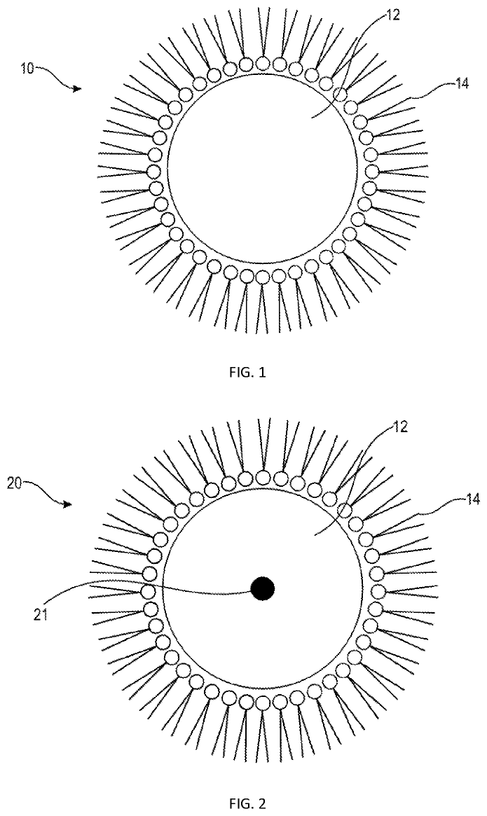

FIGS. 1 and 2 show diagrams of presumed structures of metal nanoparticles having a surfactant coating thereon. As shown in FIG. 1, metal nanoparticle 10 includes metallic core 12 and surfactant layer 14 overcoating metallic core 12. Surfactant layer 14 can contain any combination of surfactants, as described in more detail below. Metal nanoparticle 20, shown in FIG. 2, is similar to that depicted in FIG. 1, except metallic core 12 is grown about nucleus 21, which can be a metal that is the same as or different than that of metallic core 12. Because nucleus 21 is buried deep within metallic core 12 in metal nanoparticle 20 and is very small in size, it is not believed to significantly affect the overall nanoparticle properties. Nucleus 21 may comprise a salt or a metal, wherein the metal may be the same as or different than metallic core 12. In some embodiments, the metal nanoparticles can have an amorphous morphology. Although metal nanoparticles 10 and 20 in FIGS. 1 and 2 are shown as being substantially spherical, at least a portion of the metal nanoparticles may be non-spherical in shape.

As discussed above, the metal nanoparticles have a surfactant coating containing one or more surfactants upon their surface. The surfactant coating can be formed on the metal nanoparticles during their synthesis. The surfactant coating is generally lost during consolidation of the metal nanoparticles upon heating above the fusion temperature, which results in formation of bulk metal, possibly having uniform nanoporosity present therein. Formation of a surfactant coating upon metal nanoparticles during their syntheses can desirably limit the ability of the metal nanoparticles to fuse to one another prematurely, limit agglomeration of the metal nanoparticles, and promote the formation of a population of metal nanoparticles having a narrow size distribution. Porosity values may range from about 2-30% or about 2-15% following consolidation, which may be tailored based upon a number of factors, including the type of surfactant(s) that are present. At about 2% to about 15% nanoporosity, the copper composite may comprise about 85%-98% dense fused copper nanoparticles with closed pore nanoporosity having a pore size ranging from about 50 nm to about 500 nm, or about 100 nm to about 300 nm, or about 150 nm to about 250 nm, for example.

The types of metal nanoparticles suitable for use in conjunction with the various embodiments of the present disclosure are not believed to be particularly limited. Suitable metal nanoparticles can include, but are not limited to, tin nanoparticles, copper nanoparticles, aluminum nanoparticles, palladium nanoparticles, silver nanoparticles, gold nanoparticles, iron nanoparticles, cobalt nanoparticles, nickel nanoparticles, titanium nanoparticles, zirconium nanoparticles, hafnium nanoparticles, tantalum nanoparticles, molybdenum nanoparticles, tungsten nanoparticles, and the like. Combinations of these metal nanoparticles may be used as well. Micron-scale particles of these metals can be present in metal nanoparticle paste compositions containing the metal nanoparticles as well. Copper can be a particularly desirable metal for use in the embodiments of the present disclosure due to its low cost, strength, and excellent electrical and thermal conductivity values. Copper nanoparticles may be used in combination with other types of metal nanoparticles and/or micron-scale metal particles containing metals other than copper as well.

In various embodiments, the surfactant system present within the metal nanoparticles can include one or more surfactants. The differing properties of various surfactants can be used to tailor the properties of the metal nanoparticles. Factors that can be taken into account when selecting a surfactant or combination of surfactants for inclusion upon the metal nanoparticles can include, for example, ease of surfactant dissipation from the metal nanoparticles during nanoparticle fusion, nucleation and growth rates of the metal nanoparticles, the metal component of the metal nanoparticles, and the like.

In some embodiments, an amine surfactant or combination of amine surfactants, particularly aliphatic amines, can be present upon the metal nanoparticles. Amine surfactants can be particularly desirable for use in conjunction with copper nanoparticles. In some embodiments, two amine surfactants can be used in combination with one another. In other embodiments, three amine surfactants can be used in combination with one another. In more specific embodiments, a primary amine, a secondary amine, and a diamine chelating agent can be used in combination with one another. In still more specific embodiments, the three amine surfactants can include a long chain primary amine, a secondary amine, and a diamine having at least one tertiary alkyl group nitrogen substituent. Further disclosure regarding suitable amine surfactants follows hereinafter.

In some embodiments, the surfactant system can include a primary alkylamine. In some embodiments, the primary alkylamine can be a C₂-C₁₈ alkylamine. In some embodiments, the primary alkylamine can be a C₇-C₁₀ alkylamine. In other embodiments, a C₅-C₆ primary alkylamine can also be used. Without being bound by any theory or mechanism, the exact size of the primary alkylamine can be balanced between being long enough to provide an effective inverse micelle structure during synthesis versus having ready volatility and/or ease of handling during nanoparticle consolidation. For example, primary alkylamines with more than 18 carbons can also be suitable for use in the present embodiments, but they can be more difficult to handle because of their waxy character. C₇-C₁₀ primary alkylamines, in particular, can represent a good balance of desired properties for ease of use.

In some embodiments, the C₂-C₁₈ primary alkylamine can be n-hexylamine, n-heptylamine, n-octylamine, n-nonylamine, or n-decylamine, for example. While these are all straight chain primary alkylamines, branched chain primary alkylamines can also be used in other embodiments. For example, branched chain primary alkylamines such as, for example, 7-methyloctylamine, 2-methyloctylamine, or 7-methylnonylamine can be used. In some embodiments, such branched chain primary alkylamines can be sterically hindered where they are attached to the amine nitrogen atom. Non-limiting examples of such sterically hindered primary alkylamines can include, for example, t-octylamine, 2-methylpentan-2-amine, 2-methylhexan-2-amine, 2-methylheptan-2-amine, 3-ethyloctan-3-amine, 3-ethylheptan-3-amine, 3-ethylhexan-3-amine, and the like. Additional branching can also be present. Without being bound by any theory or mechanism, it is believed that primary alkylamines can serve as ligands in the metal coordination sphere but be readily dissociable therefrom during metal nanoparticle consolidation.

In some embodiments, the surfactant system can include a secondary amine. Secondary amines suitable for forming metal nanoparticles can include normal, branched, or cyclic C₄-C₁₂ alkyl groups bound to the amine nitrogen atom. In some embodiments, the branching can occur on a carbon atom bound to the amine nitrogen atom, thereby producing significant steric encumbrance at the nitrogen atom. Suitable secondary amines can include, without limitation, dihexylamine, diisobutylamine, di-t-butylamine, dineopentylamine, di-t-pentylamine, dicyclopentylamine, dicyclohexylamine, and the like. Secondary amines outside the C₄-C₁₂ range can also be used, but such secondary amines can have undesirable physical properties such as low boiling points or waxy consistencies that can complicate their handling.

In some embodiments, the surfactant system can include a chelating agent, particularly a diamine chelating agent. In some embodiments, one or both of the nitrogen atoms of the diamine chelating agent can be substituted with one or two alkyl groups. When two alkyl groups are present on the same nitrogen atom, they can be the same or different. Further, when both nitrogen atoms are substituted, the same or different alkyl groups can be present. In some embodiments, the alkyl groups can be C₁-C₆ alkyl groups. In other embodiments, the alkyl groups can be C₁-C₄ alkyl groups or C₃-C₆ alkyl groups. In some embodiments, C₃ or higher alkyl groups can be straight or have branched chains. In some embodiments, C₃ or higher alkyl groups can be cyclic. Without being bound by any theory or mechanism, it is believed that diamine chelating agents can facilitate metal nanoparticle formation by promoting nanoparticle nucleation.

In some embodiments, suitable diamine chelating agents can include N,N′-dialkylethylenediamines, particularly C₁-C₄ N,N′-dialkylethylenediamines. The corresponding methylenediamine, propylenediamine, butylenediamine, pentylenediamine or hexylenediamine derivatives can also be used. The alkyl groups can be the same or different. C₁-C₄ alkyl groups that can be present include, for example, methyl, ethyl, propyl, and butyl groups, or branched alkyl groups such as isopropyl, isobutyl, s-butyl, and t-butyl groups. Illustrative N,N′-dialkylethylenediamines that can be suitable for inclusion upon metal nanoparticles include, for example, N,N′-di-t-butylethylenediamine, N,N′-diisopropylethylenediamine, and the like.

In some embodiments, suitable diamine chelating agents can include N,N,N′,N′-tetraalkylethylenediamines, particularly C₁-C₄ N,N,N′,N′-tetraalkylethylenediamines. The corresponding methylenediamine, propylenediamine, butylenediamine, pentylenediamine or hexylenediamine derivatives can also be used. The alkyl groups can again be the same or different and include those mentioned above. Illustrative N,N,N′,N′-tetraalkylethylenediamines that can be suitable for use in forming metal nanoparticles include, for example, N,N,N′,N′-tetramethylethylenediamine, N,N,N′,N′-tetraethylethylenediamine, and the like.

Surfactants other than aliphatic amines can also be present in the surfactant system. In this regard, suitable surfactants can include, for example, pyridines, aromatic amines, phosphines, thiols, or any combination thereof. These surfactants can be used in combination with an aliphatic amine, including those described above, or they can be used in a surfactant system in which an aliphatic amine is not present. Further disclosure regarding suitable pyridines, aromatic amines, phosphines, and thiols follows below.

Suitable aromatic amines can have a formula of ArNR¹R², where Ar is a substituted or unsubstituted aryl group and R¹ and R² are the same or different. R¹ and R² can be independently selected from H or an alkyl or aryl group containing from 1 to about 16 carbon atoms. Illustrative aromatic amines that can be suitable for use in forming metal nanoparticles include, for example, aniline, toluidine, anisidine, N,N-dimethylaniline, N,N-diethylaniline, and the like. Other aromatic amines that can be used in conjunction with metal nanoparticles can be envisioned by one having ordinary skill in the art.

Suitable pyridines can include both pyridine and its derivatives. Illustrative pyridines that can be suitable for use inclusion upon metal nanoparticles include, for example, pyridine, 2-methylpyridine, 2,6-dimethylpyridine, collidine, pyridazine, and the like. Chelating pyridines such as bipyridyl chelating agents may also be used. Other pyridines that can be used in conjunction with metal nanoparticles can be envisioned by one having ordinary skill in the art.

Suitable phosphines can have a formula of PR₃, where R is an alkyl or aryl group containing from 1 to about 16 carbon atoms. The alkyl or aryl groups attached to the phosphorus center can be the same or different. Illustrative phosphines that can be present upon metal nanoparticles include, for example, trimethylphosphine, triethylphosphine, tributylphosphine, tri-t-butylphosphine, trioctylphosphine, triphenylphosphine, and the like. Phosphine oxides can also be used in a like manner. In some embodiments, surfactants that contain two or more phosphine groups configured for forming a chelate ring can also be used. Illustrative chelating phosphines can include 1,2-bisphosphines, 1,3-bisphosphines, and bis-phosphines such as BINAP, for example. Other phosphines that can be used in conjunction with metal nanoparticles can be envisioned by one having ordinary skill in the art.

Suitable thiols can have a formula of RSH, where R is an alkyl or aryl group having from about 4 to about 16 carbon atoms. Illustrative thiols that can be present upon metal nanoparticles include, for example, butanethiol, 2-methyl-2-propanethiol, hexanethiol, octanethiol, benzenethiol, and the like. In some embodiments, surfactants that contain two or more thiol groups configured for forming a chelate ring can also be used. Illustrative chelating thiols can include, for example, 1,2-dithiols (e.g., 1,2-ethanethiol) and 1,3-dithiols (e.g., 1,3-propanethiol). Other thiols that can be used in conjunction with metal nanoparticles can be envisioned by one having ordinary skill in the art.

As mentioned above, a distinguishing feature of metal nanoparticles is their low fusion temperature, which may facilitate consolidation to form bulk metal within a metal composite according to the disclosure herein. In order to facilitate their deposition in a specified location, the metal nanoparticles may be incorporated in a paste or similar formulation. Additional disclosure directed to metal nanoparticle paste compositions and similar formulations follows hereinbelow.

Metal nanoparticle paste compositions or similar formulations can be prepared by dispersing as-produced or as-isolated metal nanoparticles in an organic matrix containing one or more organic solvents and various other optional components. As used herein, the terms “nanoparticle paste formulation,” “nanoparticle paste composition” and grammatical equivalents thereof are used interchangeably and refer synonymously to a fluid composition containing dispersed metal nanoparticles that is suitable for dispensation using a desired technique. Use of the term “paste” does not necessarily imply an adhesive function of the paste alone. Through judicious choice of the organic solvent(s) and other additives, the loading of metal nanoparticles and the like, ready dispensation of the metal nanoparticles and formation of bulk metal may be realized under convenient conditions.

Cracking can sometimes occur during consolidation of the metal nanoparticles. One way in which the nanoparticle pastes of the present disclosure can promote a decreased degree of cracking and void formation following metal nanoparticle consolidation is by maintaining a high solids content. More particularly, in some embodiments, the paste compositions can contain at least about 30% metal nanoparticles by weight, particularly about 30% to about 98% metal nanoparticles by weight of the paste composition, or about 50% to about 95% metal nanoparticles by weight of the paste composition, or about 70% to about 98% metal nanoparticles by weight of the paste composition. Moreover, in some embodiments, small amounts (e.g., about 0.01% to about 15% or about 35% or about 60% by weight of the paste composition) of micron-scale particles, particularly micron-scale metal particles, can be present in addition to the metal nanoparticles. Such micron-scale metal particles can desirably promote the fusion of metal nanoparticles into a contiguous mass of bulk metal and further reduce the incidence of cracking. Instead of being liquefied and undergoing direct consolidation as is the case for the metal nanoparticles, the micron-scale metal particles can simply become joined together upon being contacted with liquefied metal nanoparticles that have been raised above their fusion temperature. These factors can reduce the porosity that results after fusing the metal nanoparticles together. The micron-scale metal particles can contain the same or different metals than the metal nanoparticles, and suitable metals for the micron-scale metal particles can include, for example, copper, silver, gold, aluminum, tin, molybdenum, tungsten, and the like. Micron-scale graphite particles may also be included, in some embodiments. Carbon nanotubes, carbon fibers, boron nitride, diamond particles, and/or graphene may be included as micron-scale particles, in some embodiments, all of which may function as CTE modifiers for tailoring the CTE according to the disclosure herein. Carbonaceous additives may increase the thermal conductivity resulting after metal nanoparticle consolidation takes place, according to some embodiments. Any of the foregoing micron-scale particles may further serve as crack deflectors to limit propagation of cracks during use, thereby increasing mechanical strength.

Decreased cracking and void formation during metal nanoparticle consolidation can also be promoted by judicious choice of the solvent(s) forming the organic matrix. A tailored combination of organic solvents can desirably decrease the incidence of cracking and void formation. More particularly, an organic matrix containing one or more hydrocarbons (saturated, monounsaturated, polyunsaturated (2 or more double bonds) or aromatic), one or more alcohols, one or more amines, and one or more organic acids can be especially effective for this purpose. One or more esters and/or one or more anhydrides may be included, in some embodiments. Alkanolamines, such as ethanolamine, may also be present in some instances. Without being bound by any theory or mechanism, it is believed that this combination of organic solvents can facilitate the removal and sequestration of surfactant molecules surrounding the metal nanoparticles during consolidation, such that the metal nanoparticles can more easily fuse together with one another. More particularly, it is believed that hydrocarbon and alcohol solvents can passively solubilize surfactant molecules released from the metal nanoparticles by Brownian motion and reduce their ability to become re-attached thereto. In concert with the passive solubilization of surfactant molecules, amine and organic acid solvents can actively sequester the surfactant molecules through a chemical interaction such that they are no longer available for recombination with the metal nanoparticles.

Further tailoring of the solvent composition can be performed to reduce the suddenness of volume contraction that takes place during surfactant removal and metal nanoparticle consolidation. Specifically, more than one member of each class of organic solvent (i.e., hydrocarbons, alcohols, amines, and organic acids), optionally in combination with one or more alkanolamines, esters or anhydrides, can be present in the organic matrix, where the members of each class have boiling points that are separated from one another by a set degree. For example, in some embodiments, the various members of each class can have boiling points that are separated from one another by about 20° C. to about 50° C. By using such a solvent mixture, sudden volume changes due to rapid loss of solvent can be minimized during metal nanoparticle consolidation, since the various components of the solvent mixture can be removed gradually over a broad range of boiling points (e.g., about 50° C. to about 200° C.).

In various embodiments, at least some of the one or more organic solvents can have a boiling point of about 100° C. or greater. In other various embodiments, at least some of the one or more organic solvents can have a boiling point of about 200° C. or greater. In some or other embodiments, the one or more organic solvents can have boiling points ranging between about 50° C. and about 200° C., or between about 50° C. and about 250° C., or between about 50° C. and about 300° C., or between about 50° C. and about 350° C. Use of high boiling organic solvents can desirably increase the pot life of the metal nanoparticle paste compositions and limit the rapid loss of solvent, which can otherwise lead to cracking and void formation during nanoparticle consolidation. In some embodiments, at least one of the organic solvents can have a boiling point that is higher than the boiling point(s) of the surfactant(s) associated with the metal nanoparticles. Accordingly, surfactant(s) can be removed from the metal nanoparticles by evaporation before removal of the organic solvent(s) takes place.

In some embodiments, the organic matrix can contain one or more alcohols, which may be C₂-C₁₂, C₄-C₁₂ or C₇-C₁₂ in more particular embodiments. In various embodiments, the alcohols can include monohydric alcohols, diols, or triols. One or more glycol ethers (e.g., diethylene glycol and triethylene glycol), alkanolamines (e.g., ethanolamine, triethanolamine, and the like), or any combination thereof may be present in certain embodiments, which may be present alone or in combination with other alcohols. Various glymes may be present with the one or more alcohols in some embodiments. In some embodiments, one or more hydrocarbons can be present in combination with one or more alcohols. As discussed above, it is believed that alcohol (and optionally glymes and alkanolamines) and hydrocarbon solvents can passively promote the solubilization of surfactants as they are removed from the metal nanoparticles by Brownian motion and limit their re-association with the metal nanoparticles. Moreover, hydrocarbon and alcohol solvents only weakly coordinate with metal nanoparticles, so they do not simply replace the displaced surfactants in the nanoparticle coordination sphere. Illustrative but non-limiting examples of alcohol and hydrocarbon solvents that can be present include, for example, light aromatic petroleum distillate (CAS 64742-95-6), hydrotreated light petroleum distillates (CAS 64742-47-8), tripropyleneglycol methyl ether, ligroin (CAS 68551-17-7, a mixture of C₁₀-C₁₃ alkanes), diisopropyleneglycol monomethyl ether, diethyleneglycol diethyl ether, 2-propanol, 2-butanol, t-butanol, 1-hexanol, 2-(2-butoxyethoxy)ethanol, and terpineol. In some embodiments, polyketone solvents can be used in a like manner.

In some embodiments, the organic matrix can contain one or more amines and one or more organic acids. In some embodiments, the one or more amines and one or more organic acids can be present in an organic matrix that also includes one or more hydrocarbons and one or more alcohols. As discussed above, it is believed that amines and organic acids can actively sequester surfactants that have been passively solubilized by hydrocarbon and alcohol solvents, thereby making the surfactants unavailable for re-association with the metal nanoparticles. Thus, an organic solvent that contains a combination of one or more hydrocarbons, one or more alcohols, one or more amines, and one or more organic acids can provide synergistic benefits for promoting the consolidation of metal nanoparticles. Illustrative but non-limiting examples of amine solvents that can be present include, for example, tallowamine (CAS 61790-33-8), alkyl (C₈-C₁₈) unsaturated amines (CAS 68037-94-5), di(hydrogenated tallow)amine (CAS 61789-79-5), dialkyl (C₈-C₂₀) amines (CAS 68526-63-6), alkyl (C₁₀-C₁₆)dimethyl amine (CAS 67700-98-5), alkyl (C₁₄-C₁₈) dimethyl amine (CAS 68037-93-4), dihydrogenated tallowmethyl amine (CAS 61788-63-4), and trialkyl (C₆-C₁₂) amines (CAS 68038-01-7). Illustrative but non-limiting examples of organic acid solvents that can be present in the nanoparticle paste compositions include, for example, octanoic acid, nonanoic acid, decanoic acid, caprylic acid, pelargonic acid, undecylic acid, lauric acid, tridecylic acid, myristic acid, pentadecanoic acid, palmitic acid, margaric acid, stearic acid, nonadecylic acid, α-linolenic acid, stearidonic acid, oleic acid, and linoleic acid.

In some embodiments, the organic matrix can include more than one hydrocarbon, more than one alcohol, optionally more than one glyme (glycol ether), more than one amine, and more than one organic acid. For example, in some embodiments, each class of organic solvent can have two or more members, or three or more members, or four or more members, or five or more members, or six or more members, or seven or more members, or eight or more members, or nine or more members, or ten or more members. Moreover, the number of members in each class of organic solvent can be the same or different. Particular benefits of using multiple members of each class of organic solvent are described hereinafter. Higher boiling organic solvents may provide safety advantages.

One particular advantage of using multiple members within each class of organic solvent can include the ability to provide a wide spread of boiling points in the metal nanoparticle paste compositions. By providing a wide spread of boiling points, the organic solvents can be removed gradually as the temperature rises while affecting metal nanoparticle consolidation, thereby limiting volume contraction and disfavoring cracking. By gradually removing the organic solvent in this manner, less temperature control may be needed to affect slow solvent removal than if a single solvent with a narrow boiling point range was used. In some embodiments, the members within each class of organic solvent can have a window of boiling points ranging between about 50° C. and about 200° C., or between about 50° C. and about 250° C., or between about 100° C. and about 200° C., or between about 100° C. and about 250° C., or between about 150° C. and about 300° C., or between about 150° C. and about 350° C. In more particular embodiments, the various members of each class of organic solvent can each have boiling points that are separated from one another by at least about 20° C., specifically about 20° C. to about 50° C. More specifically, in some embodiments, each hydrocarbon can have a boiling point that differs by about 20° C. to about 50° C. from other hydrocarbons in the organic matrix, each alcohol can have a boiling point that differs by about 20° C. to about 50° C. from other alcohols in the organic matrix, each amine can have a boiling point that differs by about 20° C. to about 50° C. from other amines in the organic matrix, and each organic acid can have a boiling point that differs by about 20° C. to about 50° C. from other organic acids in the organic matrix. The more members of each class of organic solvent that are present, the smaller the differences become between the boiling points. By having smaller differences between the boiling points, solvent removal can be made more continual, thereby limiting the degree of volume contraction that occurs at each stage. A reduced degree of cracking can occur when four to five or more members of each class of organic solvent are present (e.g., four or more hydrocarbons, four or more alcohols, four or more amines, and four or more organic acids; or five or more hydrocarbons, five or more alcohols, five or more amines, and five or more organic acids), each having boiling points that are separated from one another within the above range.

In various embodiments, the metal nanoparticles used in the metal nanoparticle paste compositions can be about 20 nm or less in size. In other various embodiments, metal nanoparticles may be up to about 75 nm in size. As discussed above, metal nanoparticles in this size range have fusion temperatures that are significantly lower than those of the corresponding bulk metal and readily undergo consolidation with one another as a result. In some embodiments, metal nanoparticles that are about 20 nm or less in size can have a fusion temperature of about 220° C. or below (e.g., a fusion temperature in the range of about 140° C. to about 220° C.) or about 200° C. or below, which can provide advantages that are noted above. In some embodiments, at least a portion of the metal nanoparticles can be about 10 nm or less in size, or about 5 nm or less in size. In more specific embodiments, at least a portion of the metal nanoparticles can range from about 1 nm in size to about 20 nm in size, or from about 1 nm in size to about 10 nm in size, or from about 1 nm in size to about 5 nm in size, or from about 3 nm in size to about 7 nm in size, or from about 5 nm in size to about 20 nm in size. In some embodiments, substantially all of the metal nanoparticles can reside within these size ranges. In some embodiments, larger metal nanoparticles can be combined in the metal nanoparticle paste compositions with metal nanoparticles that are about 20 nm in size or less. For example, in some embodiments, metal nanoparticles ranging from about 1 nm to about 10 nm in size can be combined with metal nanoparticles that range from about 25 nm to about 50 nm in size, or with metal nanoparticles that range from about 25 nm to about 100 nm in size, or with metal nanoparticles that range from about 25 nm to about 150 nm in size. As further discussed below, micron-scale metal particles and/or nanoscale particles can also be included in the metal nanoparticle paste compositions in some embodiments. Although larger metal nanoparticles and micron-scale metal particles may not be liquefiable at the low temperatures of their smaller counterparts, they can still become consolidated upon contacting the smaller metal nanoparticles that have been liquefied at or above their fusion temperature, as generally discussed above.

In addition to metal nanoparticles and organic solvents, other additives can also be present in the metal nanoparticle paste compositions. Such additional additives can include, for example, rheology control aids, thickening agents, micron-scale conductive additives, nanoscale conductive additives, and any combination thereof. Chemical additives can also be present. As discussed hereinafter, the inclusion of micron-scale conductive additives, such as micron-scale metal particles, can be particularly advantageous. Nanoscale or micron-scale diamond or other thermally conductive additives may be desirable to include in some instances for promoting more efficient heat transfer and also further tailoring the CTE. Suitable CTE modifiers that may be in the micron-scale or nanoscale size range may include, but are not limited to, carbon fibers, diamond particles, boron nitride particles, aluminum nitride particles, carbon nanotubes, graphene, and the like.

In some embodiments, the metal nanoparticle paste compositions can contain about 0.01% to about 15% micron-scale metal particles by weight, or about 1% to about 10% micron-scale metal particles by weight, or about 1% to about 5% micron-scale metal particles by weight, or about 0.1% to about 35% micron-scale metal particles by weight. Inclusion of micron-scale metal particles in the metal nanoparticle paste compositions can desirably reduce the incidence of cracking that occurs during consolidation of the metal nanoparticles when forming bulk metal. Without being bound by any theory or mechanism, it is believed that the micron-scale metal particles can become consolidated with one another as the metal nanoparticles are liquefied and form a transient liquid coating upon the surface of the micron-scale metal particles. In some embodiments, the micron-scale metal particles can range from about 500 nm to about 100 microns in size in at least one dimension, or from about 500 nm to about 10 microns in size in at least one dimension, or from about 100 nm to about 5 microns in size in at least one dimension, or from about 100 nm to about 10 microns in size in at least one dimension, or from about 100 nm to about 1 micron in size in at least one dimension, or from about 1 micron to about 10 microns in size in at least one dimension, or from about 5 microns to about 10 microns in size in at least one dimension, or from about 1 micron to about 100 microns in size in at least one dimension. The micron-scale metal particles can contain the same metal as the metal nanoparticles or contain a different metal. Thus, copper composites may be formed in the present disclosure by combining copper nanoparticles and a CTE modifier with one another, optionally in further combination with micron-scale copper particles. Similarly, metal alloys can be fabricated by including micron-scale metal particles in the paste compositions with a metal differing from that of the metal nanoparticles. Metal alloys may also be formed by combining different types of metal nanoparticles with one another. Suitable micron-scale metal particles can include, for example, Cu, Ni, Al, Fe, Co, Mo, W, Ag, Zn, Sn, Au, Pd, Pt, Ru, Mn, Cr, Ti, V, Mg or Ca particles. Non-metal particles such as, for example, Si, B, and C-based micron-scale particles can be used in a like manner. In some embodiments, the micron-scale metal particles can be in the form of metal flakes, such as high aspect ratio copper flakes, for example. Thus, in some embodiments, the metal nanoparticle paste compositions described herein can contain a mixture of copper nanoparticles and high aspect ratio copper flakes or another type of micron-scale copper particles in combination with a CTE modifier. Specifically, in some embodiments, the metal nanoparticle paste compositions can contain about 30% to about 90% copper nanoparticles by weight and about 0.01% to about 15% or 1% to 35% high aspect ratio copper flakes by weight.

Other micron-scale metal particles that can be used equivalently to high aspect ratio metal flakes include, for example, metal nanowires and other high aspect ratio particles, which can be up to about 300 microns in length. The ratio of metal nanoparticles to metal nanowires may range from about 10:1 to about 40:1, according to various embodiments. Suitable nanowires may have a length of about 5 microns to about 50 microns, and a diameter of about 100 nm to about 200 nm, for example.

In some embodiments, nanoscale conductive additives can also be present in the metal nanoparticle paste compositions. These additives can desirably provide further structural stabilization and reduce shrinkage during metal nanoparticle consolidation. Moreover, inclusion of nanoscale conductive additives can increase electrical and thermal conductivity values that can approach or even exceed that of the corresponding bulk metal following nanoparticle consolidation, which can be desirable for promoting heat transfer according to the disclosure herein. The nanoscale conductive additives can exhibit at least one size in a nanoscale dimension, such as at least one dimension ranging from about 5 nm to about 500 nm or about 10 nm to about 200 nm. In some embodiments, the nanoscale conductive additives can further have a size in at least one dimension ranging from about 1 micron to about 50 microns, or ranging from about 50 microns to about 100 microns, or ranging from about 100 microns to about 300 microns. Suitable nanoscale conductive additives can include, for example, carbon nanotubes, boron nitride, boron carbide, graphene, nanodiamond, nanographite, and the like, any of which may also function as a CTE modifier. When present, the metal nanoparticle paste compositions can contain about 1% to about 20% or about 1% to about 10% nanoscale conductive additives by weight, or about 1% to about 5% nanoscale conductive additives by weight, or about 5% to about 15% nanoscale conductive additives by weight.

Additional substances that can also optionally be present in the metal nanoparticle paste compositions include, for example, flame retardants, UV protective agents, antioxidants, carbon black, graphite, fiber materials (e.g., chopped carbon fiber materials), diamond, and the like.

In some more specific embodiments, suitable nanoparticle paste compositions may further comprise diamond particles. A suitable size of diamond particles may be sized as large as possible to limit grain boundaries that need to be crossed by phonons during heat transfer while remaining sufficiently small such that dispensability of the metal nanoparticle paste composition is not compromised.

In still more specific embodiments, diamond particles suitable for use in the metal nanoparticle paste compositions may have a size ranging from about 1 micron to about 1000 microns, or from about 0.5 micron to about 500 microns, which can provide for good particle dispersion and acceptable paste dispensability. Diamond particles having a size ranging from about 200 microns to about 250 microns or about 1 micron to about 10 microns can represent a good compromise between providing effective dispersion and a minimized grain boundary for discouraging phonon scattering. Other suitable size ranges for the diamond particles can range from about 25 microns to about 150 microns, or about 50 microns to about 250 microns, or from about 100 microns to about 250 microns, or from about 100 microns to about 200 microns, or from about 150 microns to about 250 microns, or from about 1 micron to about 100 microns, or from about 10 microns to about 50 microns, or from about 5 microns to about 25 microns.

In illustrative embodiments, the composites can include about 10% to about 75% diamond particles by volume after metal nanoparticle consolidation has taken place to form a monolithic metal body (metal composite, such as a copper composite containing a CTE modifier). Other conductive particles may be present in a similar compositional range.

Admixture of copper nanoparticles and diamond particles to form a copper composite may be desirable for several reasons. Copper is low in cost compared to most other metals, is impedance matched relatively well with diamond, and bears high thermal conductivity on its own. In some embodiments, impedance matching can be further improved by including a carbide-forming additive to form a thin layer (single atom to <10 nm thick layer) of carbide upon the diamond particles. As such, the combination of copper nanoparticles and diamond particles can provide very effective heat transfer in the various embodiments of the present disclosure. For establishing electronic communication between various board layers, copper also affords high electrical conductivity as well. Depending on the particular composition utilized, such as due to the amount of electrically non-conductive additives, the electrical conductivity may be about 30-50% IACS, or about 35-60% IACS, or about 50-75% IACS, or about 55-90% IACS, or about 60-98% IACS (International Annealed Copper Standard).

Nanoparticle paste compositions suitable for use in the present disclosure can be formulated according to any of the disclosure hereinabove. According to some embodiments, multiple metals may be present in the metal nanoparticle paste compositions. In some or other embodiments, suitable metal nanoparticle paste compositions can include a mixture of metal nanoparticles, other nano-sized particles (i.e., particles having a dimension of about 200 nm or less), and/or micron-scale particles, including micron-scale metal particles. The metal nanoparticle paste compositions may comprise copper nanoparticles, according to more specific embodiments.

Various heat pipes and printed circuit boards utilizing heat pipes may be formed, at least in part, from copper nanoparticles and copper nanoparticle paste compositions. It is to be appreciated that alternative metal nanoparticles may be utilized to form heat pipes comprising different metals, as may be needed to facilitate CTE matching to some ceramic materials within a heat-producing component. Thus, it is to be appreciated that any embodiment utilizing copper or copper nanoparticles in the disclosure following hereinafter may utilize alternative metals or metal nanoparticles depending on application-specific needs.

Heat pipes of the present disclosure may comprise a structure having a sealed outer shell comprising a copper composite that comprises a CTE modifier, and a working fluid movable within an internal space defined within the sealed outer shell. The working fluid may move freely within the internal space of the heat pipe, or defined channels may be present in which the working fluid may move. Various heat pipe configurations are described hereinafter in reference to the drawings. Both wicking and oscillating heat pipe configurations are contemplated in the disclosure herein. That is, heat pipes of the present disclosure may comprise a wicking structure interposed between the sealed outer shell and a hollow core, or a flow channel may be defined upon a surface of the sealed outer shell.

In various embodiments, the copper composite may be formed through consolidation of copper nanoparticles with micron-size copper particles and the CTE modifier. The copper nanoparticles, the micron-size copper particles, and the CTE modifier may define a copper nanoparticle paste composition, as described in more detail above. In some embodiments, suitable copper nanoparticle paste compositions may comprise about 30 wt. % to about 60 wt. % copper nanoparticles or about 5 wt. % to about 50 wt. % micron-size copper particles, and an effective amount of the CTE modifier to target a specified CTE. The CTE modifier may be present in an amount ranging from about 1% to about 35% by weight, or about 4% to about 8% by weight, or about 5% to about 15% by weight, or about 10% to about 20% by weight. Exemplary guidance of how to select particular CTE modifiers and amounts thereof to achieve specified CTE values in a copper composite are provided hereinbelow. The micron-size copper particles may be omitted in some embodiments.

Suitable CTE modifiers may include, but are not limited to, diamond particles, graphite/pitch-based carbon fibers (e.g., having a diameter of about 10 microns), W particles, Mo particles, diamond particles, boron nitride particles, boron carbide particles, aluminum nitride particles, carbon nanotubes, graphene, the like, and any combination thereof. Carbon-based additives, for example, can achieve about 2-3 ppm thermal expansion when added at about 16% by volume, or about 7 ppm thermal expansion when added at about 9% by volume, or about 6 ppm when added at about 11% by volume.

Adding diamond at about 45% by volume can achieve about 5-6 ppm thermal expansion depending on density (82%). At about 37% loading by volume and 93% density, the thermal expansion provided by diamond may be about 6 ppm. At a diamond loading of more than about 50% by volume, the thermal expansion drops below about 5 ppm.

Consolidated copper nanoparticles by themselves exhibit a thermal expansion of about 7-12 ppm depending on the process conditions and density. With increasing density, the thermal expansion approaches that of bulk copper (17 ppm). At about 91% density, the thermal expansion is about 7-8 ppm, and at about 93% density the thermal expansion increases to about 10-11 ppm. At about 98% density, the thermal expansion reaches about 12 ppm. Even at such high density values, the thermal expansion is still below the value for bulk copper, which is presumed to arise from the nanoporosity present following copper nanoparticle consolidation.

Addition of micron-scale metal particles to metal nanoparticles (e.g., copper nanoparticles) can increase the thermal expansion to reach 17 ppm and beyond depending on the specific metal. Addition of Al particles, for example, having a bulk CTE of about 23-24 ppm, can increase the CTE of the resulting composite to a value exceeding that of bulk copper. Addition of about 55% micron-scale copper powder results in a thermal expansion of about 14 ppm at a density of 96%.

Carbon nanotubes may increase the thermal conductivity of copper up to about 600 W/m·K from a value in the low 400s W/m·K for bulk copper alone. The degree of thermal conductivity modification achievable with carbon nanotubes may depend upon the length of the carbon nanotubes, with longer carbon nanotubes exceeding a thermal conductivity value of about 600 W/m·K. Such modification of the thermal conductivity may occur in concert with CTE modification in the manner discussed above.

In the absence of surface modifiers, suitable CTE modifiers may afford a reduction in thermal conductivity from the initial value of about 400 W/m·K for bulk copper to a value of about 150 W/m·K again depending on porosity. The decrease in thermal conductivity may be counteracted, at least to some degree, by including metal powders, such as micron-scale metal particles or diamond particles, for example. At about 25% diamond by volume, the thermal conductivity may be about 240 W/m·K for a copper-diamond composite. By including a wetting agent in a copper-diamond composite, a thermal conductivity exceeding 1000 W/m·K may be achieved with a 50% by volume diamond load. At a carbonaceous additive load of about 10% by volume, a thermal conductivity of around 300 W/m·K can be achieved. Thus, the present disclosure may facilitate balancing the CTE and thermal conductivity of a copper composite to promote robust heat transfer.

Suitable working fluids are not believed to be especially limited and may include any liquid that may effectively transfer heat from a first location to a second location in the heat pipe. Additional characteristics of suitable working fluids may include compatibility of the material(s) defining an inner surface of the heat pipe. Suitable working fluids may include, but are not limited to, liquid helium, liquid ammonia, liquid nitrogen, water, methanol, ethanol, mercury, liquid sodium, liquid indium, glycols such as ethylene glycol or glycol-water mixtures, and the like. Fluorocarbon refrigerants may also be used. The anticipated operating temperature range may determine the suitability of a given working fluid for inclusion in the heat pipe. In more particular examples, the working fluid may be chosen to undergo vaporization (at the hot end of the heat pipe) and undergo condensation (at the cold end of the heat pipe) under anticipated operating temperatures.

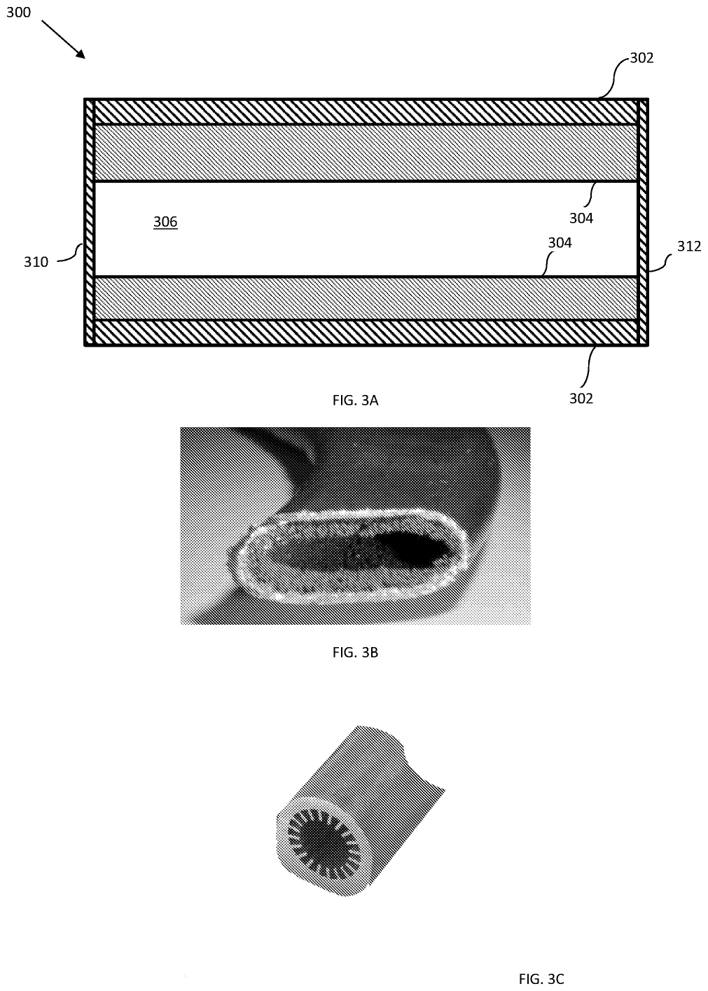

FIG. 3A is a cross-sectional diagram of an illustrative heat pipe comprising a wicking structure adjacent to a hollow core. Heat pipe 300 includes sealed outer shell 302 contiguous with wicking structure 304, optionally penetrating into wicking structure 304. Sealed outer shell 302 is formed from a copper composite comprising a CTE modifier in the disclosure herein, wherein the copper composite may be formed upon consolidation of a plurality of copper nanoparticles. Ends 310 and 312 may be capped (sealed) with the copper composite as well, thereby sealing a working fluid (not shown) within hollow core 306. Although not apparent from FIG. 3A, the copper composite at ends 310 and 312 may at least partially impinge upon hollow core 306. Other techniques for sealing ends 310 and 312 are also possible, as discussed hereinafter. Wicking structure 304 is interposed between hollow core 306 and sealed outer shell 302 and may contact the working fluid housed within hollow core 306. The working fluid (not shown) moves within hollow core 306 from a hot end (e.g., an end of heat pipe 300 in thermal contact with a heat-producing component) to a cold end (e.g. an end of heat pipe 300 in thermal communication with a heat sink, such as ambient atmosphere, a marine environment, or a radiator to outer space). Vaporization of the working fluid may occur at the hot end, followed by condensation of the working fluid at the cold end upon release of latent heat. After the working fluid vapor has condensed at the cold end, the condensed working fluid may migrate back to the hot end via wicking structure 304, with or without gravity assistance depending on design of heat pipe 300, to facilitate further heat transfer. Details for constructing heat pipe 300 using metal nanoparticles are provided hereinbelow.

In various embodiments, wicking structure 304 may comprise a foam, a metal mesh, a plurality of grooves, or any combination thereof. Suitable foams may include, for example, Al foams, SiC foams, Cu foams, or the like, any of which may be reticulated foams. Suitable foams may be open cell reticulated foams, sponge-like, or similar structures. FIG. 3B is a photo showing a cutaway end view of an illustrative heat pipe comprising a metal mesh or foam wicking structure. The heat pipe in FIG. 3B is partially flattened to facilitate its disposition between a heat source and heat sink in a specified location. FIG. 3C is a diagram showing a cutaway end view of an illustrative heat pipe comprising grooves as a wicking structure. Although shown in a largely rounded configuration, the heat pipe in FIG. 3C may alternately be at least partially flattened, like the heat pipe shown in FIG. 3B, or be in another geometric shape.

Heat pipe 300 or a similar heat pipe may be formed by providing wicking structure 304 in tubular form and infiltrating a copper nanoparticle paste composition a few microns deep within an outer portion of wicking structure 304. In non-limiting examples, the depth of penetration may be about 100 microns or less, or about 75 microns or less, or about 50 microns or less, or about 25 microns or less, such as about 10 microns to about 50 microns, or about 25 microns to about 75 microns, or about 50 microns to about 100 microns. A layer of the copper nanoparticle paste composition may remain on the outer surface of the tubular form, which is also contiguous with the copper nanoparticle paste composition infiltrated within wicking structure 304. Upon consolidation of the copper nanoparticles, sealed outer shell 302 may be formed upon the tubular form and optionally at least partially penetrate into the tubular form. Wicking structure 304 may be provided by any continuous or near-continuous production line affording an elongate tubular form (e.g., a continuous extrusion process) suitable for contacting a working fluid within the internals of heat pipe 300. Infiltration of the copper nanoparticle paste composition upon and within wicking structure 304 may take place in conjunction with manufacturing the elongate tubular form, or infiltration may take place separately in one or more processing operations. In addition, the outer surface of wicking structure 304 may be further electroplated following copper nanoparticle consolidation to ensure hermetic sealing of heat pipe 300. Porosity of wicking structure 304, the particle loading in the copper nanoparticle paste composition and its density, the copper nanoparticle paste composition application technique, and the like may impact the depth to which the copper nanoparticle paste composition penetrates into wicking structure 304 as well as the thickness of sealed outer shell 302 that is obtained. In illustrative embodiments, incorporation of the copper nanoparticle paste composition upon and within wicking structure 304 may take place by spreading or painting the copper nanoparticle paste composition onto the outer surface of the elongate tubular form, or by injection molding or hot pressing the copper nanoparticle paste composition thereon. Following application of the copper nanoparticle paste composition, wicking structure 304 may be exposed to conditions that promote copper nanoparticle consolidation. For example, according to various embodiments, the copper nanoparticles may be heated at or above the fusion temperature or pressure may be applied.

In non-limiting examples, the copper nanoparticle paste composition may be applied to wicking structure 304 in a continuous process using a doctor-blade like approach, such as through feeding wicking structure 304 through an orifice with a conical shape that pushes the paste composition into the structure. The depth of penetration may be controlled by the viscosity and density of the paste composition, as well as the size and amount of the CTE modifier and thermal conductivity additives. A higher load of either component may reduce the penetration depth. Wicking structure 304 is then placed under pressure using a clamp shell or wrapped with a suitable material like KAPTON or other commercial shrink-wrap materials that can handle processing temperature of 220-240° C. Thereafter, a thin layer of a copper nanoparticles may then be applied to close out any remaining pores or voids. For this step, no pressure is necessary, but can be used again in a similar fashion, if desired. Finally, the resulting elongate structure can be electroplated to close out any possible last pores or voids and to provide a smooth surface finish. In the end structure, a solid wall structure is obtained in which all layers have fused together.

Consolidation of the metal nanoparticles provides a continuous matrix of bulk copper upon and interpenetrating within at least a portion of wicking structure 304 to afford sealed outer shell 302. If needed, electroplating may be performed after metal nanoparticle consolidation has taken place to complete formation of sealed outer shell 302 and provide hermetic sealing of heat pipe 300 once ends 310 and 312 are closed off.

After metal nanoparticle consolidation and optional further electroplating, the thickness of sealed outer shell 302 may range from about 100 microns to about 1000 microns, or about 100 microns to about 300 microns, or about 200 microns to about 300 microns, or about 300 microns to about 500 microns. Wicking structure 304 may range in thickness from about 0.1 microns to about 3000 microns, or about 500 microns to about 3000 microns, or about 500 microns to about 1000 microns, or about 1000 microns to about 3000 microns.

While ends 310 and 312 of wicking structure 304 remain open, a working fluid has not yet been loaded therein. In non-limiting examples, ends 310 and 312 may be closed off by welding or spot welding, threaded or non-threaded plugs or caps, compression (pinch-off), or valving, preferably while applying a vacuum. A copper nanoparticle paste composition may also be loaded into one or both of ends 310 or 312 and consolidated to promote sealing in an alternative manner. Closure of ends 310 and 312 may occur separately or at the same time. Loading of the working fluid in heat pipe 300 may take place before either of ends 310 or 312 is closed or after at least one of ends 310 or 312 is closed. For example, end 310 may be closed first, working fluid may then be loaded into hollow core 306, and end 312 may then be closed off to seal the working fluid within hollow core 306. Bonding of heat pipe 300 to a heat source, such as a printed circuit board or similar heat-producing component, may take place before loading the working fluid and closing off end 312. Alternately, the working fluid may be loaded in heat pipe 300, and bonding to a heat source may occur in conjunction with closing off end 312. Still further alternately, heat pipe 300 may be loaded with the working fluid and closed off on both of ends 310 and 312, either sequentially or at the same time, and bonding to a heat source may take place separately thereafter (e.g., with a metal nanoparticle paste composition to form a bonding layer). If heat pipe 300 has already been fully assembled, spot heating may be performed to promote bonding of heat pipe 300 to a heat source or a heat sink via a bonding layer formed from metal nanoparticles, since more widely dispersed heat may otherwise be conveyed away from the desired heating location by heat pipe 300 and/or heat pipe 300 may be damaged. Localized, rapid heating to promote bonding to a heat source or heat sink via a bonding layer may be performed with a laser or Xe lamp, for example.

A heat source or heat sink may be bonded to ends 310 and 312 of heat pipe 300. Alternately, the heat source or heat sink may be bonded to a sidewall of heat pipe 300 (e.g., upon sealed outer shell 302). As still another option, heat pipe 300 may be bonded to a thermally conductive substrate that is in thermal communication with a heat-producing component.

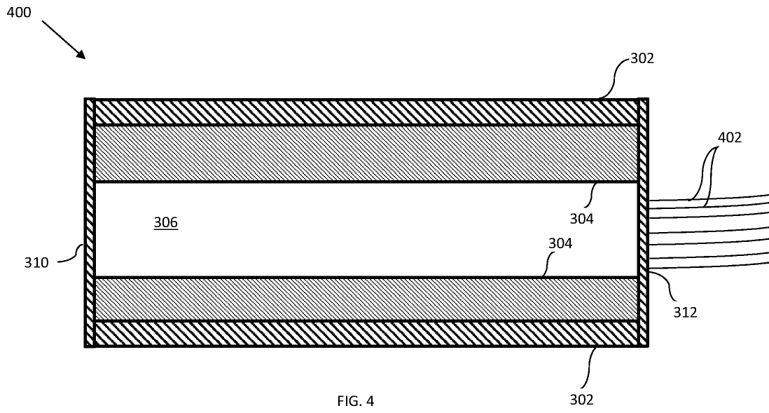

When a copper nanoparticle paste composition is used to close at least one of ends 310 or 312, a plurality of conductive fibers may extend from one end of the heat pipe. The conductive fibers may further facilitate dissipation of heat from the heat pipe to a heat sink, since the conductive fibers may provide a large surface area to facilitate heat dissipation. FIG. 4 is a cross-sectional diagram of an illustrative heat pipe comprising a wicking structure adjacent to a hollow core in which a plurality of conductive fibers 402 extend from one end of the heat pipe. Other than conductive fibers 402 extending from end 312, heat pipe 400 is similar to heat pipe 300 (FIG. 3) and may be better understood by reference thereto. Common reference characters are used to denote elements having similar structure and function. Although conductive fibers 402 are shown in FIG. 4 with their ends terminating in end 312 of heat pipe 400, it is to be appreciated that the ends of conductive fibers 402 may also extend into the interior of heat pipe 400 (i.e., within hollow core 306), such that they may contact the working fluid therein. When so configured, direct contact of conductive fibers 402 with the working fluid may facilitate still more effective heat transfer. In addition, conductive fibers 402 may provide a high surface area upon which condensation of the working fluid may occur within hollow core 306.

Suitable conductive fibers that may be present in the heat pipes disclosed herein include, but are not limited to, graphite fiber bundles, which may exhibit thermal conductivity values that are double or more that of bulk copper (e.g., 800-1100 W/m·K). Other types of suitable conductive fibers may include, but are not limited to, metal fibers (e.g., Al or Cu fibers), diamond fibers, carbon nanotubes or carbon nanotube fibers, or any combination thereof. Suitable fiber lengths may be about 2-8 inches, depending on fiber flexibility. Suitable fiber diameters may be about 5-50 microns, or about 5-10 microns, or about 5-20 microns, or about 30-50 microns. The fibers may be optionally bifurcated, such that more fiber ends are present external to the heat pipe than are embedded in the end of the heat pipe. Conductive fibers may also be in the form of porous foams extending from the heat pipe, in which case a cooling fluid, such as air or a liquid, may pass through the pores of the foam external to the heat pipe to aid in removing transferred heat from the conductive fibers. When the conductive fibers in the form of porous foams are used, the conductive fibers may be positioned such that working fluid remains sealed within the hollow core of the heat pipe.

To introduce conductive fibers 402 to heat pipe 400, end 312 may be closed off with a copper nanoparticle paste composition, such as during a hot pressing or injection molding operation. The copper nanoparticle paste composition may first be applied to end 312, and conductive fibers 402 may then be inserted into the unconsolidated copper nanoparticle paste composition. Following consolidation of the copper nanoparticles, conductive fibers 402 may become firmly affixed to end 312 of heat pipe 400 in a matrix of bulk copper formed from the copper nanoparticle paste composition.

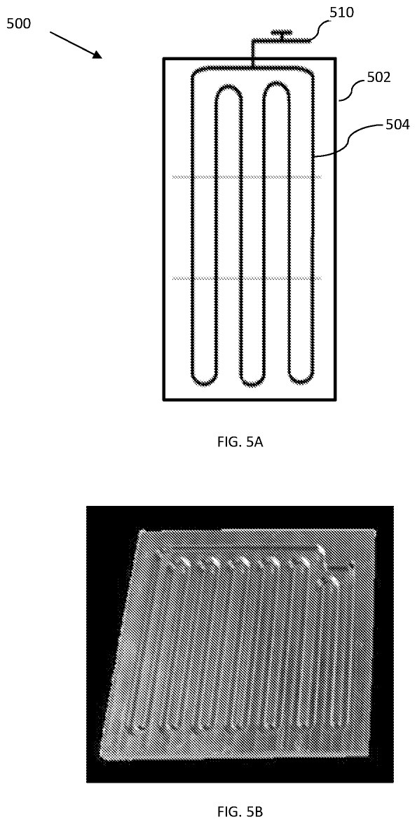

FIG. 5A is a cross-sectional top view diagram of an illustrative oscillating heat pipe, which may be formed from a copper composite according to the disclosure herein. Heat pipe 500 includes flow channel 504, which is disposed in a non-limiting serpentine pattern within a top surface of copper block 502. Flow channel 504 may be defined in a closed loop, wherein at least one portion of the closed loop, commonly multiple portions of the closed loop, extend between a hot end and a cold end of heat pipe 500. In an oscillating heat pipe, such as oscillating heat pipe 500 shown in FIG. 5A, the working fluid (not shown) moves as multiple fluid slugs within the closed loop defined by flow channel 504 as heat is absorbed at a hot end and migrates to the cold end. Void space may exist between each fluid slug within flow channel 504. The fluid slugs may at least partially vaporize near the hot end and condense near the cold end of heat pipe 500 to result in a pulsating motion of the fluid slugs though the closed loop.

Referring still to FIG. 5A, copper block 502 may be formed from a copper composite, such as the illustrative copper composites formed from copper nanoparticles and a CTE modifier, as described above. In various embodiments, copper block 502 may be formed through consolidation of copper nanoparticles within a copper nanoparticle paste composition shaped to form a monolithic structure having flow channel 504 patterned in a top surface thereof following metal nanoparticle consolidation. In other embodiments, injection moulding or metal casting may be used to make a net shape part having all or a portion of flow channel 504 (e.g., a hemisphere) defined therein. Once copper block 502 has been formed, a complementary part (e.g., a flat plate of the same composition as copper block 502) may be applied over copper block 502 to hermetically seal flow channel 504 once a working fluid has been loaded therein. Metal nanoparticles may be utilized to promote bonding between copper block 502 and a complementary part to promote sealing of flow channel 504 such that a working fluid may flow therethrough. A second portion of copper nanoparticles, separate from the copper nanoparticles used to form the sealed outer shell of the heat pipe, may be utilized for this purpose. Alternately or in addition, a second portion of copper nanoparticles may be used to promote bonding of copper block 502 to a heat-producing component.

FIG. 5B is a photo showing a perspective view of an illustrative copper block having flow channels defined therein. Not shown in FIGS. 5A and 5B is a top copper block (complementary part), which encloses flow channel 502 and maintains the working fluid therein. FIG. 5C is a cross-sectional side view diagram of heat pipe 500, in which flow channel 504 is defined in copper block 502 and complementary part 506 seals flow channel 504 to confine the working fluid therein. Like copper block 502, complementary part 506 may be formed from a copper composite, which may be further CTE matched to copper block 502, if desired. Otherwise, complementary part 506 may be formed through conventional machining techniques. In various embodiments, complementary part 506 may be formed through consolidation of copper nanoparticles within a copper nanoparticle paste composition. A copper nanoparticle paste composition may be utilized to form a metallurgical bond between copper block 502 and complementary part 506. Valve 510 may be present to load the working fluid into flow channel 504 once it has been sealed with complementary part 506. At least a partial vacuum may be applied after sealing and before loading the working fluid into flow channel 504. The vacuum may promote entry of the working fluid into flow channel 504.

The heat pipes disclosed herein may be in any specified shape. Without limitation, the heat pipes may be round, prismatic, ovular, triangular, rectangular, flat, partially flattened, or the like. The heat pipes may be bent or substantially straight, particularly after being connected between a heat source and a heat sink. In some embodiments, the heat pipes may contact a top or bottom surface of a heat-producing component and bend to conform to the surface of a substrate upon which the heat-producing component is located. Other than fitting into a particular working environment, the dimensions of the heat pipes are not considered to be particularly limited.

The heat pipes disclosed herein may be utilized to dissipate heat from a heat-producing component associated with a printed circuit board. The heat-producing component may comprise a ceramic such as, for example, Si (CTE=3.5), SiC (CTE=4.2 ppm), GaN (CTE=5.6 ppm), or AlN (CTE=4.5 ppm). The CTE modifier and amount thereof that is combined with the copper nanoparticles may be adjusted to match the CTE of the heat-producing component within a desired tolerance. In non-limiting examples, the CTE of the heat pipe may match the CTE of the heat-producing component within a tolerance about ±50%, or within about ±25%, or within about ±20%, or within about ±15%, or within about ±10%, or within about ±5%, or within about ±4%, or within about ±3%, or within about ±2%, or within about ±1%.

Printed circuit boards of the present disclosure may comprise: a heat-producing component located upon or at least partially recessed within an electrically insulating substrate, and at least one heat pipe in thermal communication with the heat-producing component, in which the at least one heat pipe is CTE-matched to the heat-producing component. The electrically insulating substrate may also be thermally insulating, such as FR4, or thermally conductive, such as those comprising AlN or SiN. In various examples, the at least one heat pipe has a sealed outer shell comprising a copper composite that comprises a CTE modifier, and a working fluid movable within an internal space housed within the sealed outer shell. Suitable heat pipes may comprise a wicking structure or a sealed flow channel through which the working fluid moves, as discussed in more detail above. The at least one heat pipe may be bonded to the heat-producing component via a bonding layer comprising a copper composite that is also CTE-matched to the heat-producing component and the copper composite comprising the sealed outer shell. Alternately, the heat pipe may be bonded to an electrically insulating substrate having sufficient thermal conductivity, rather than being bonded to a heat-producing component.

The heat-producing component may be located upon a top surface of the electrically insulating substrate or at least partially recessed (buried) within the electrically insulating substrate. The at least one heat pipe may be bonded to a top surface or a bottom surface of the heat-producing component, one or more heat pipes may be bonded to a side surface of the heat-producing component, or any combination thereof. When bonded to the bottom surface of the heat-producing component, the at least one heat pipe may extend through the electrically insulating substrate. Additional details concerning how the one or more heat pipes may be connected to the heat-producing component are provided hereinafter.

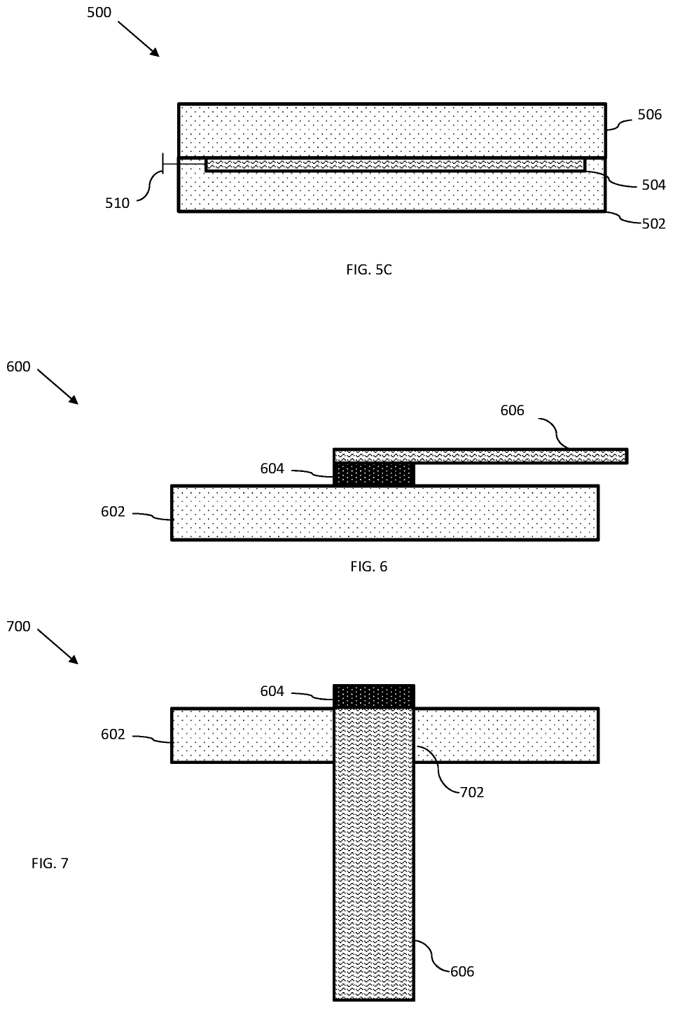

FIG. 6 is a diagram showing a side-view of a heat pipe bonded to a top surface of a heat-producing component. Such configurations may be utilized in flip chip packages, for example. As shown, PCB 600 includes electrically insulating substrate 602 and heat-producing component 604 thereupon. Heat pipe 606 is bonded to a top surface of heat-producing component 604 and is directed to conduct excess heat away therefrom. Heat pipe 606 may be a heat pipe of the present disclosure, described in more detail above. Although heat pipe 606 is shown in a substantially straight and unsupported configuration in FIG. 6, it is to be appreciated that heat pipe 606 may alternately be bent or curved, and/or conform to at least a portion of the surface of PCB 600. In still another example, heat-producing component 604 may be at least partially recessed into the surface of electrically insulating substrate 602, in which case heat pipe 606 may again be oriented in a similar manner to that depicted in FIG. 6.

FIG. 7 is a diagram showing a side-view of a heat pipe bonded to a bottom surface of a heat-producing component. In this configuration, heat pipe 606 extends through via 702 (i.e., a through-plane via) defined in electrically insulating substrate 602 of PCB 700. Via 702 may be suitably sized for heat pipe 606 to extend therethrough, such that a surface of heat pipe 606 may contact a bottom surface of heat-producing component 604. Heat pipe 606 may again be a heat pipe of the present disclosure, described in more detail above. Likewise, heat-producing component 604 may be at least partially recessed into the surface of electrically insulating component 602, with heat pipe 606 oriented in a similar manner to that depicted in FIG. 7. Although via 702 is shown in FIG. 7 as being substantially the same width as heat-producing component 604, it is to be appreciated that via 702 may be smaller in width such that heat pipe 606 contacts less than an entire surface of heat-producing component 604. It is also to be appreciated that heat pipe 606 may alternately be bent or curved after passing through via 702, and/or conform to at least a portion of the bottom surface of PCB 700.

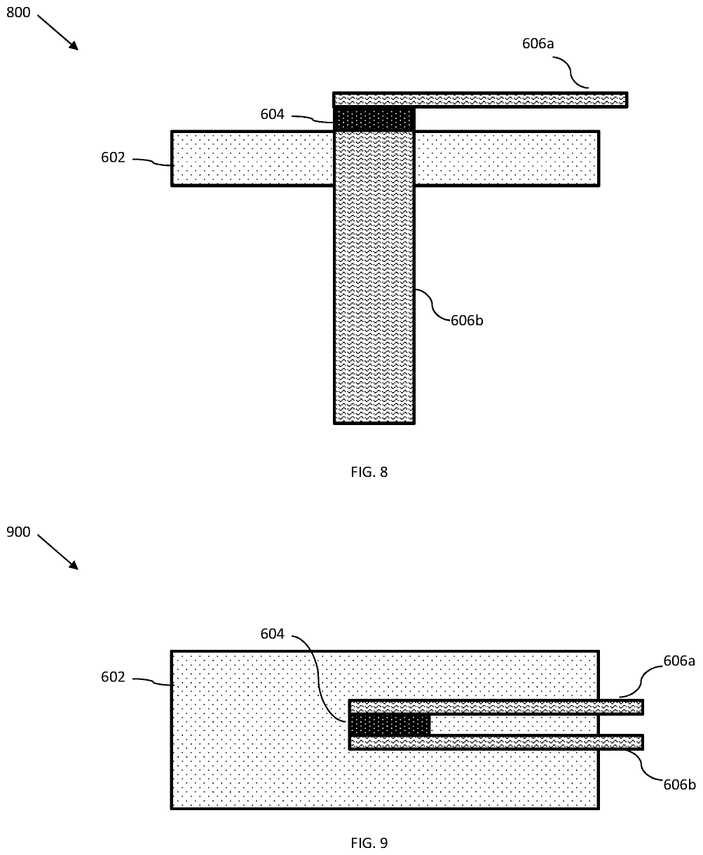

Heat pipes may also be bonded to the top and bottom surfaces of the heat-producing component, as shown in FIG. 8. FIG. 8 is a diagram showing a side-view of heat pipes bonded to both a top surface and a bottom surface of a heat-producing component. In PCB 800, heat pipe 606a is bonded to the top surface of heat-producing component 604 in a manner similar to that depicted in FIG. 6, and heat pipe 606b extends through electrically insulating substrate 602 and is bonded to a bottom surface of heat-producing component 604 in a manner similar to that depicted in FIG. 7. Thus, the present disclosure may facilitate attachment of multiple heat pipes to a heat-producing component, such that heat removal may occur from multiple faces of the PCB.

FIG. 9 is a diagram showing a top view of multiple heat pipes bonded to a side surface of a heat-producing component. In FIG. 9, heat-producing component 604 is located upon or at least partially recessed within electrically insulating substrate 602. Heat pipes 606a and 606b contact and are bonded to a side surface of heat-producing component 604, optionally such that heat pipes 606a and 606b run along the surface of electrically insulating substrate 602. Although two heat pipes (606a and 606b) are shown with side bonding to heat-producing component 604 in PCB 900, it is appreciated that one or more than two heat pipes may be bound similarly, optionally in combination with a heat pipe bonded to the top and/or bottom surface of heat-producing component 604 (FIGS. 6-8). Side bonding of one or more heat pipes to heat-producing component 604 may facilitate stacking of multiple PCB layers, wherein one or more heat pipes are sandwiched between adjacent PCB layers and facilitate heat removal laterally from the PCB. By rejecting excess heat laterally via a heat pipe extending between two PCB layers, PCB manufacturing may be simplified by not having to machine the electrically insulating substrate to accommodate a heat pipe extending through multiple PCB layers from a top or bottom surface of heat-producing component 604. It is to be appreciated that top and bottom heat pipes (not shown) may be present, particularly for the top and bottom layers of a multi-layer PCB.

In the case that an electrically insulating substrate has high thermal conductivity, heat pipes of the present disclosure may be located upon at least one surface of the electrically insulating substrate. Thus, instead of heat being removed directly from a heat-producing component, the heat may be transferred from the heat-producing component through the electrically insulating substrate, and the heat may then be removed via a heat pipe of the present disclosure. That is, in the case of an electrically insulating substrate having high thermal conductivity, heat removal from the heat-producing component may occur indirectly.

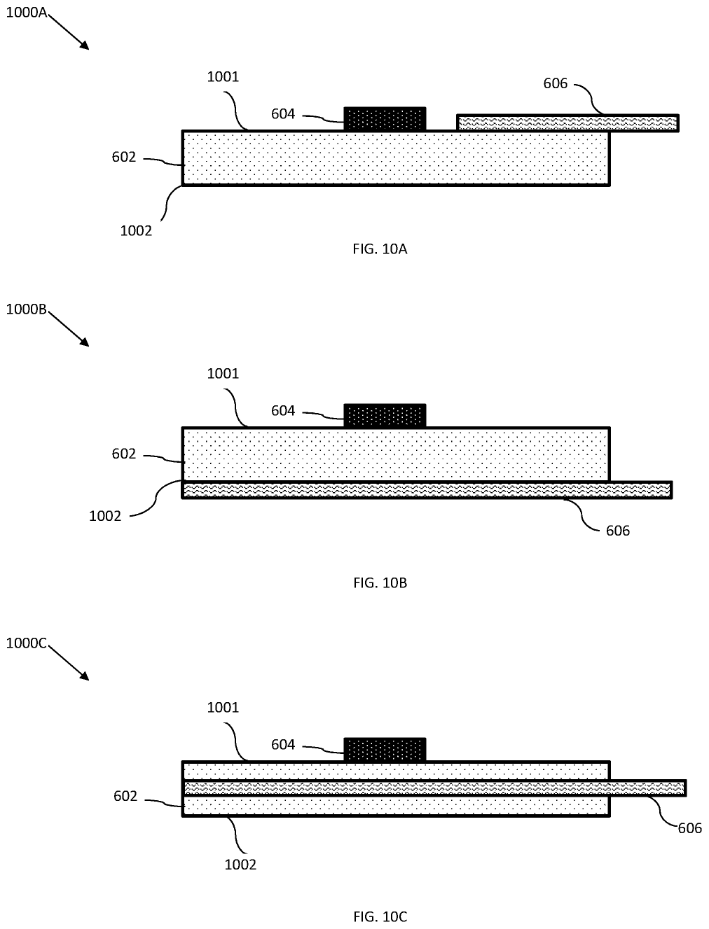

FIGS. 10A-10C are diagrams showing side-views of a heat pipe located upon an electrically insulating substrate having high thermal conductivity. In PCB 1000A of FIG. 10A, heat pipe 606 is located upon top surface 1001 of electrically insulating substrate 602. Heat-producing component 604 is also located upon top surface 1001 but remains spaced apart from heat pipe 606, such that heat transfer takes place through electrically insulating substrate 602. PCB 1000B in FIG. 10B is similar to PCB 1000A in FIG. 10A, except heat pipe 606 is located on bottom surface 1002, i.e., opposite to heat-producing component 604 on top face 1001. Likewise, PCB 1000C in FIG. 10C incorporates heat pipe 606 internally within electrically insulating substrate 602 to accomplish a similar result.

Accordingly, PCBs including a heat pipe of the present disclosure may be single-layer or multi-layer, according to various embodiments. Multi-layer PCBs can contain individual layers that are laminated together to define vias and other board features. Bonding between multiple PCB layers may be accomplished with an appropriate adhesive in a laying up process, for example. The number of layers in a multi-layer PCB is not considered to be particularly limited and may be up to about 10 individual PCB layers, for example, each of which may contain a heat-producing component in need of heat removal through use of a heat pipe according to the disclosure herein.

In various embodiments, the sealed outer shell and a bonding layer connecting a heat pipe to a heat-producing component may comprise copper and be formed from copper nanoparticles, more particularly a copper nanoparticle paste composition containing additives suitable to modify the CTE of the bonding layer to match that of the heat-producing component. The CTE modifier may comprise carbon fibers, diamond particles, boron nitride, aluminum nitride, carbon nanotubes, graphene, or the like. A particular CTE modifier and amount thereof may be selected to provide a desired degree of CTE modification. Other additives may be present in the copper nanoparticle paste composition to facilitate dispensation and handling, as discussed in greater detail above.

Accordingly, methods of the present disclosure may comprise: providing an elongate wicking structure having an outer surface and an inner surface defining a hollow core; applying a copper nanoparticle paste composition to the outer surface, in which the copper nanoparticle paste composition comprises a plurality of copper nanoparticles, a plurality of micron-size copper particles, and a CTE modifier; consolidating the copper nanoparticles to form a sealed outer shell upon the outer surface of the elongate wicking structure, optionally electroplating to complete formation of the sealed outer shell; partially loading the hollow core with a working fluid; and closing off at least one end portion of the sealed outer shell. In various embodiments, at least one of the end portions may be closed off with a copper nanoparticle paste composition, followed by consolidating the copper nanoparticles therein, as discussed in more detail above. Suitable copper nanoparticle paste compositions, CTE modifiers, and heat exchanger configurations are described in more detail above.

If forming a heat pipe comprising a plurality of fibers extending therefrom, the methods may further comprise placing a plurality of thermally conductive fibers in a second portion of copper nanoparticle paste composition upon an end portion of the heat pipe. Upon consolidating the copper nanoparticles within the copper nanoparticle paste composition, the plurality of fibers may become affixed to the end portion of the heat pipe. Optionally, at least a portion of the conductive fibers may extend into the hollow core of the heat pipe and contact the working fluid therein.

Embodiments disclosed herein include:
A. Heat pipes. The heat pipes comprise: a structure having a sealed outer shell comprising a copper composite that comprises a coefficient of thermal expansion (CTE) modifier; and a working fluid effective to move within an internal space housed within the sealed outer shell.
B. Printed circuit boards comprising: a heat-producing component located upon an electrically insulating substrate; and at least one heat pipe in thermal communication with the heat-producing component, the at least one heat pipe comprising: a structure having a sealed outer shell comprising a copper composite that comprises a coefficient of thermal expansion (CTE) modifier; and a working fluid effective to move within an internal space housed within the sealed outer shell. Optionally, the electrically insulating substrate may also be thermally insulating, such as FR4 and similar epoxy substrates, or thermally conductive, such as aluminum nitride or silicon carbide.
C. Methods for making a heat pipe. The methods comprise: providing an elongate wicking structure defining having an outer surface and an inner surface defining a hollow core; applying a copper nanoparticle paste composition to the outer surface, the copper nanoparticle paste composition comprising a plurality of copper nanoparticles, a plurality of micron-size copper particles, and a coefficient of thermal expansion (CTE) modifier; consolidating the copper nanoparticles to form a sealed outer shell upon the wicking structure; partially loading the hollow core with a working fluid; and closing off at least one end portion of the sealed outer shell.

Each of embodiments A, B, and C may have one or more of the following additional elements in any combination:
Element 1: wherein the copper composite is formed through consolidation of copper nanoparticles with micron-size copper particles and the CTE modifier.
Element 2: wherein the internal space comprises a wicking structure adjacent to a hollow core.
Element 3: wherein the wicking structure comprises a foam, a wire mesh, a plurality of grooves or any combination thereof.
Element 4: wherein the internal space comprises a flow channel defined upon an inner surface of the sealed outer shell.
Element 5: wherein the copper composite has a uniform nanoporosity of about 2% to about 30%.
Element 6: wherein the CTE modifier comprises carbon fibers, W particles, Mo particles, diamond particles, boron nitride, carbon nanotubes, or any combination thereof.
Element 7: wherein the heat pipe further comprises a plurality of thermally conductive fibers extending from an end portion of the structure, optionally wherein at least a portion of the thermally conductive fibers extend into the internal space and contact the working fluid.
Element 7A: wherein the PCB further comprises a plurality of thermally conductive fibers extending from an end portion of the structure, optionally wherein at least a portion of the thermally conductive fibers extend into the internal space and contact the working fluid.
Element 7B: wherein the method further comprises placing a plurality of thermally conductive fibers in the copper nanoparticle paste composition and extending from the at least one end portion, optionally wherein at least a portion of the thermally conductive fibers extend into the hollow core and contact the working fluid.
Element 8: wherein the at least one heat pipe is bonded to the heat-producing component via a bonding layer comprising a copper composite that is CTE-matched to the copper composite comprising the sealed outer shell.
Element 9: wherein the heat-producing component is located upon a surface of the electrically insulating substrate, and: the at least one heat pipe is bonded to a top surface of the heat-producing component, one or more heat pipes are bonded to a side surface of the heat-producing component, the at least one heat pipe is bonded to a bottom surface of the heat-producing component and the at least one heat pipe extends through the electrically insulating substrate, or any combination thereof.
Element 10: wherein the at least one end portion is closed off by applying the copper nanoparticle paste composition thereto, and consolidating the copper nanoparticles therein.

By way of non-limiting example, exemplary combinations applicable to A, B, C include, but are not limited to: 1 and 2; 1-3; 1 and 4; 1 and 5; 1 and 6; 1, and 7, 7A or 7B; 1 and 8; 1 and 9; 1 and 10; 2 and 4; 2-4; 2 and 5; 2 and 6; 2, and 7, 7A or 7B; 2 and 8; 2 and 9; 2 and 10; 4 and 5; 4 and 6; 4, and 7, 7A or 7B; 4 and 8; 4 and 9; 4 and 10; 5 and 6; 5, and 7, 7A or 7B; 5 and 8; 5 and 9; 5 and 10; 6, and 7, 7A or 7B; 6 and 8; 6 and 9; 6 and 10; 7, 7A or 7B, and 8; 7, 7A or 7B, and 9; 7, 7A or 7B, and 10; 8 and 9; 8 and 10; 8-10; 7B, and 8-10; and 9 and 10.

Additional embodiments disclosed herein include:
A′: Heat pipes. The heat pipes comprise: a structure having a sealed outer shell comprising a copper composite that comprises a coefficient of thermal expansion (CTE) modifier; and a working fluid movable within an internal space defined within the sealed outer shell, the internal space comprising a wicking structure interposed between the sealed outer shell and a hollow core, or a flow channel defined upon a surface of the sealed outer shell.
B′: Printed circuit boards (PCBs). The PCBs comprise: a heat-producing component located upon or at least partially recessed within an electrically insulating substrate; and at least one heat pipe in thermal communication with the heat-producing component, the at least one heat pipe comprising: a structure having a sealed outer shell comprising a copper composite that comprises a coefficient of thermal expansion (CTE) modifier; and a working fluid movable within an internal space defined within the sealed outer shell, the internal space comprising wicking structure interposed between the sealed outer shell and a hollow core, or a flow channel defined upon a surface of the sealed outer shell.
C′: Methods for making a heat pipe. The methods comprise: providing an elongate wicking structure having an outer surface and an inner surface defining a hollow core; applying a copper nanoparticle paste composition to the outer surface, the copper nanoparticle paste composition comprising a plurality of copper nanoparticles, a plurality of micron-size copper particles, and a coefficient of thermal expansion (CTE) modifier; consolidating the copper nanoparticles to form a sealed outer shell upon the outer surface of the elongate wicking structure; partially loading the hollow core with a working fluid; and closing off at least one end portion of the sealed outer shell to confine the working fluid in the hollow core.

Each of embodiments A′, B′, and C′ may have one or more of the following additional elements in any combination:
Element 1′: wherein the copper composite is formed through consolidation of copper nanoparticles with micron-size copper particles and the CTE modifier.
Element 2′: wherein the wicking structure comprises a foam, a wire mesh, a plurality of grooves, or any combination thereof.
Element 3′: wherein the sealed outer shell penetrates into at least a portion of the wicking structure.
Element 4′: wherein a complementary part contacts the sealed outer shell and seals an upper surface of the flow channel.
Element 5′: wherein the copper composite has a uniform nanoporosity of about 2% to about 30%.
Element 6′: wherein the CTE modifier comprises carbon fibers, W particles, Mo particles, diamond particles, boron nitride, aluminum nitride, carbon nanotubes, graphene, or any combination thereof.
Element 7′: wherein the heat pipe further comprises a plurality of thermally conductive fibers extending from an end portion of the structure, optionally wherein at least a portion of the thermally conductive fibers extend into the internal space and contact the working fluid.
Element 8′: wherein the at least one heat pipe is bonded to the heat-producing component via a bonding layer comprising a copper composite that is CTE-matched to the copper composite comprising the sealed outer shell.
Element 9′: wherein: the at least one heat pipe is bonded to a top surface of the heat-producing component, one or more heat pipes are bonded to a side surface of the heat-producing component, the at least one heat pipe is bonded to a bottom surface of the heat-producing component and the at least one heat pipe extends through the electrically insulating substrate, or any combination thereof.
Element 10′: wherein the at least one end portion is closed off by applying a second portion of the copper nanoparticle paste composition to the at least one end portion, and consolidating the copper nanoparticles therein.
Element 11′: wherein the method further comprises placing a plurality of thermally conductive fibers in the second portion of the copper nanoparticle paste composition and extending from the at least one end portion, optionally wherein at least a portion of the thermally conductive fibers extend into the hollow core and contact the working fluid.

By way of non-limiting example, exemplary combinations applicable to A′, B′, and C′ include, but are not limited to, 1′ and 2′; 1′ and 3′; 1′ and 4′; 1′ and 5′; 1′ and 6′; 1′ and 7′; 2′ and/or 3′, and 5′; 2′ and/or 3′, and 6′; 2′ and/or 3′, and 7′; 4′ and 5′; 4′ and 6′ 4′ and 7′; 5′ and 6′; 5′ and 7′; and 6′ and 7′. Any of the foregoing, or any one of 1′-7′ may be in further combination with 8′ and 9′, 8′, 9′; 10′ and 11′, 10′, or 11′.

Unless otherwise indicated, all numbers expressing quantities of ingredients, properties such as molecular weight, reaction conditions, and so forth used in the present specification and associated claims are to be understood as being modified in all instances by the term “about.” Accordingly, unless indicated to the contrary, the numerical parameters set forth in the following specification and attached claims are approximations that may vary depending upon the desired properties sought to be obtained by the embodiments of the present invention. At the very least, and not as an attempt to limit the application of the doctrine of equivalents to the scope of the claim, each numerical parameter should at least be construed in light of the number of reported significant digits and by applying ordinary rounding techniques.

One or more illustrative embodiments incorporating the features of the present disclosure are presented herein. Not all features of a physical implementation are described or shown in this application for the sake of clarity. It is understood that in the development of a physical embodiment incorporating the present disclosure, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for those of ordinary skill in the art and having benefit of this disclosure.

Therefore, the present disclosure is well adapted to attain the ends and advantages mentioned as well as those that are inherent therein. The particular embodiments disclosed above are illustrative only, as the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present invention. The disclosure herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

1. A heat pipe comprising:
a structure having a sealed outer shell comprising a copper composite that comprises a coefficient of thermal expansion (CTE) modifier; and
a working fluid movable within an internal space defined within the sealed outer shell, the internal space comprising a wicking structure interposed between the sealed outer shell and a hollow core, or a flow channel defined upon a surface of the sealed outer shell.

2. The heat pipe of claim 1, wherein the copper composite is formed through consolidation of copper nanoparticles with micron-size copper particles and the CTE modifier.

3. The heat pipe of claim 1, wherein the wicking structure comprises a foam, a wire mesh, a plurality of grooves, or any combination thereof.

4. The heat pipe of claim 1, wherein the sealed outer shell penetrates into at least a portion of the wicking structure.

5. The heat pipe of claim 1, wherein a complementary part contacts the sealed outer shell and seals an upper surface of the flow channel.

6. The heat pipe of claim 1, wherein the copper composite has a uniform nanoporosity of about 2% to about 30%.

7. The heat pipe of claim 1, wherein the CTE modifier comprises carbon fibers, W particles, Mo particles, diamond particles, boron nitride, aluminum nitride, carbon nanotubes, graphene, or any combination thereof.

8. The heat pipe of claim 1, further comprising:
a plurality of thermally conductive fibers extending from an end portion of the structure, optionally wherein at least a portion of the thermally conductive fibers extend into the internal space and contact the working fluid.

9. A printed circuit board (PCB) comprising:
a heat-producing component located upon or at least partially recessed within an electrically insulating substrate; and
at least one heat pipe in thermal communication with the heat-producing component, the at least one heat pipe comprising:
a structure having a sealed outer shell comprising a copper composite that comprises a coefficient of thermal expansion (CTE) modifier; and
a working fluid movable within an internal space defined within the sealed outer shell, the internal space comprising wicking structure interposed between the sealed outer shell and a hollow core, or a flow channel defined upon a surface of the sealed outer shell.

10. The PCB of claim 9, wherein the copper composite is formed through consolidation of copper nanoparticles with micron-size copper particles and the CTE modifier.

11. The PCB of claim 9, wherein the wicking structure comprises a foam, a wire mesh, a plurality of grooves, or any combination thereof.

12. The PCB of claim 9, wherein the sealed outer shell penetrates into at least a portion of the wicking structure.

13. The PCB of claim 9, wherein a complementary part contacts the sealed outer shell and seals an upper surface of the flow channel.

14. The PCB of claim 9, wherein the copper composite has a uniform nanoporosity of about 2% to about 30%.

15. The PCB of claim 9, wherein the at least one heat pipe is bonded to the heat-producing component via a bonding layer comprising a copper composite that is CTE-matched to the copper composite comprising the sealed outer shell.

16. The PCB of claim 9, wherein: the at least one heat pipe is bonded to a top surface of the heat-producing component, one or more heat pipes are bonded to a side surface of the heat-producing component, the at least one heat pipe is bonded to a bottom surface of the heat-producing component and the at least one heat pipe extends through the electrically insulating substrate, or any combination thereof.

17. The PCB of claim 9, wherein the CTE modifier comprises carbon fibers, W particles, Mo particles, diamond particles, boron nitride, aluminum nitride, carbon nanotubes, graphene, or any combination thereof.

18. The PCB of claim 9, further comprising: a plurality of thermally conductive fibers extending from an end portion of the structure, optionally wherein at least a portion of the thermally conductive fibers extend into the internal space and contact the working fluid.

19. A method comprising:
providing an elongate wicking structure having an outer surface and an inner surface defining a hollow core;
applying a copper nanoparticle paste composition to the outer surface, the copper nanoparticle paste composition comprising a plurality of copper nanoparticles, a plurality of micron-size copper particles, and a coefficient of thermal expansion (CTE) modifier;
consolidating the copper nanoparticles to form a sealed outer shell upon the outer surface of the elongate wicking structure; partially loading the hollow core with a working fluid; and
closing off at least one end portion of the sealed outer shell to confine the working fluid in the hollow core.

20. The method of claim 19, wherein the at least one end portion is closed off by applying a second portion of the copper nanoparticle paste composition to the at least one end portion, and consolidating the copper nanoparticles therein.

21. The method of claim 20, further comprising: placing a plurality of thermally conductive fibers in the second portion of the copper nanoparticle paste composition and extending from the at least one end portion, optionally wherein at least a portion of the thermally conductive fibers extend into the hollow core and contact the working fluid.

22. The method of claim 19, wherein the wicking structure comprises a foam, a wire mesh, a plurality of grooves, or any combination thereof.

23. The method of claim 19, wherein the copper composite has a uniform nanoporosity of about 2% to about 30%.

24. The method of claim 19, wherein the CTE modifier comprises carbon fibers, W particles, Mo particles, diamond particles, boron nitride, aluminum nitride, carbon nanotubes, graphene, or any combination thereof.

25. The method of claim 19, wherein the sealed outer shell penetrates into at least a portion of the wicking structure.

26. The heat pipe of claim 2, wherein the copper nanoparticles have a surfactant coating containing one or more surfactants on their surface.

27. The heat pipe of claim 2, wherein the copper composite comprises about 30% to about 98% copper nanoparticles by weight and about 0.1 to about 15% micron-scale particles by weight.

28. The heat pipe of claim 2, wherein at least a portion of the copper nanoparticles are in a range of from about 1 to about 10 nm in size and the remaining copper nanoparticles are in a range of 25 to about 50 nm in size.
